(19) United States
(12) Patent Application Publication
(10) Pub. No.: US 2004/0033440 A1
(43) Pub. Date: Feb. 19, 2004

(54) Photoacid generators, chemically amplified positive resist compositions, and patterning process

(76) Inventors: Kazunori Maeda, Niigata-ken (JP); Youichi Ohsawa, Niigata-ken (JP); Satoshi Watanabe, Niigata-ken (JP)

Correspondence Address: BIRCH STEWART KOLASCH & BIRCH, PO BOX 747, FALLS CHURCH, VA, 22040-0747, US

(21) Appl. No.: 10/636,654

(22) Filed: Aug. 8, 2003

(30) Foreign Application Priority Data
Aug. 9, 2002 (JP) 2002-233510

(51) Int. Cl. G03F 7/004; G03F 7/20; G03F 7/38

(52) U.S. Cl. 430/270.1; 430/296; 430/311; 430/330; 430/913; 430/921; 430/922

(57) ABSTRACT

Photoacid generators capable of generating 2,4,6-triisopropylbenzenesulfonic acid upon exposure to actinic radiation are suited for use in chemically amplified positive resist compositions. Due to the low diffusion of 2,4,6-triisopropylbenzenesulfonic acid, the compositions have many advantages including improved resolution, improved focus latitude, and minimized line width variation or shape degradation even on long-term PED.

This invention relates to photoacid generators for chemically amplified positive resist compositions, chemically amplified positive resist compositions comprising the photoacid generators, and a patterning process using the same. The chemically amplified positive resist compositions are sensitive to such radiation as UV, deep UV, electron beams, x-rays, excimer laser beams, y-rays, and synchrotron radiation and suitable for the microfabrication of integrated circuits.

### BACKGROUND OF THE INVENTION

While a number of efforts are currently being made to achieve a finer pattern rule in the drive for higher integration and operating speeds in LSI devices, deep-ultraviolet lithography is thought to hold particular promise as the next generation in microfabrication technology.

One technology that has attracted a good deal of attention recently utilizes as the deep UV light source a high-intensity KrF excimer laser, especially an ArF excimer laser featuring a shorter wavelength. There is a desire to have a microfabrication technique of finer definition by combining exposure light of shorter wavelength with a resist material having a higher resolution.

In this regard, the recently developed, acid-catalyzed, chemical amplification type positive resist materials are expected to comply with the deep UV lithography because of their many advantages including high sensitivity, resolution and dry etching resistance. The chemical amplification type resist materials include positive working materials that leave the unexposed areas with the exposed areas removed and negative working materials that leave the exposed areas with the unexposed areas removed.

On use of the chemical amplification type, positive working, resist compositions, a resist film is formed by dissolving a resin having acid labile groups as a binder and a compound capable of generating an acid upon exposure to radiation (to be referred to as photoacid generator) in a solvent, applying the resist solution onto a substrate by a variety of methods, and evaporating off the solvent optionally by heating. The resist film is then exposed to radiation, for example, deep UV through a mask of a predetermined pattern. This is optionally followed by post-exposure baking (PEB) for promoting acid-catalyzed reaction. The exposed resist film is developed with an aqueous alkaline developer for removing the exposed area of the resist film, obtaining a positive pattern profile. The substrate is then etched by any desired technique. Finally the remaining resist film is removed by dissolution in a remover solution or ashing, leaving the substrate having the desired pattern profile.

The chemical amplification type, positive working, resist compositions adapted for KrF excimer lasers generally use a phenolic resin, for example, polyhydroxystyrene in which some or all of the hydrogen atoms of phenolic hydroxyl groups are protected with acid labile protective groups. Iodonium salts, sulfonium salts, bissulfonyldiazomethane compounds, N-sulfonyloxydicarboxyimide compounds and O-arylsulfonyloxime compounds are typically used as the photoacid generator. If necessary, there are added additives, for example, a dissolution inhibiting or promoting compound in the form of a carboxylic acid and/or phenol derivative having a molecular weight of up to 3,000 in which some or all of the hydrogen atoms of carboxylic acid and/or phenolic hydroxyl groups are protected with acid labile groups, a carboxylic acid compound for improving dissolution characteristics, a basic compound for improving contrast, and a surfactant for improving coating characteristics.

JP-A 2002-508774 describes O-arylsulfonyloxime compounds which are given an absorbing ability not only in the ultraviolet region, but also in the visible region, and thus absorb light of longer wavelengths to generate acids. They are mainly used in negative resist compositions. Illustrative compounds have the following structure.

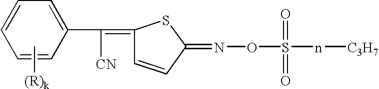

As the requisite pattern size is reduced, however, even the use of the above resist compositions encounters problems including poor resolution and low stability to the environment.

The environmental stability is generally divided into two categories. One stability problem is that when the duration between exposure and post-exposure bake (PEB) is prolonged, that is, in the case of post exposure delay (PED), the acid generated diffuses through the resist film so that acid deactivation occurs if acid labile groups are less scissile or acid decomposition reaction occurs if acid labile groups are more scissile, often leading to variations of the pattern profile. In chemically amplified positive resist compositions having acid labile groups including primarily acetal groups, for example, the line width of unexposed areas is often narrowed.

The other problem of environmental stability is that the acid generated upon exposure is deactivated with airborne bases on the resist film or bases on the substrate beneath the resist film. This phenomenon is often found when a photoacid generator capable of generating an acid having a high acid strength is used or when the air in a clean room is contaminated with basic compounds.

This problem is addressed by rendering the acid labile groups in the resin more scissile to acid or by reducing (or weakening) the acid strength of the acid generated. The acidity-basicity largely varies with the type of an organic bottom antireflection coating (BARC) beneath the resist film. The deactivation of the generated acid by a basic organic antireflection film reveals itself as footing of the pattern profile and prevents formation of a rectangular shaped pattern, posing a serious problem particularly in proximity to the resolution limit.

With respect to the resolution, improvements are being made by rendering the acid labile groups in the resin more scissile by acid, using basic additives, optimizing process conditions or using photoacid generators of generating low diffusible sulfonic acids. These approaches, however, are still unsatisfactory.

The low diffusible acids that photoacid generators generate upon exposure to light include 10-camphorsulfonic acid and octanesulfonic acid. Since all these sulfonic acids have a weaker acid strength than fluorinated alkylsulfonic acids and arylsulfonic acids commonly employed in the prior art, the amount of acid must compensate for the weakness of acid strength. That is, a more amount of acid must be generated, which in turn, requires to extend the exposure time, often leading to a low productivity.

Of the low diffusible arylsulfonic acids, sulfonium salts capable of generating 2,4,6-triisopropylbenzenesulfonic acid are known from JP-A 5-222257. Since the sulfonium salts have substantial light absorption in proximity to the wavelength 248 nm of a KrF excimer laser, they, when incorporated in resist compositions, act to reduce the transmittance of a resist film. As a result, the amount of acid generated differs between the top and the bottom of the film. Instead of a pattern profile of rectangular shape, there results a trapezoidal pattern or a pattern whose bottom portion is not removed (in the case of positive resists).

The photoacid generators to generate low diffusible, highly lipophilic alkylsulfonic acids and arylsulfonic acids, especially the O-arylsulfonyloxime compound, shown below, to generate 10-camphorsulfonic acid and the bisarylsulfonyldiazomethane, shown below, are highly soluble in resist solvents, but have low affinity to (or low solubility in) developers. They can thus be left on the substrate as insoluble residues (in the form of the photoacid generator alone or combined with the resin) after development and/or resist removal.

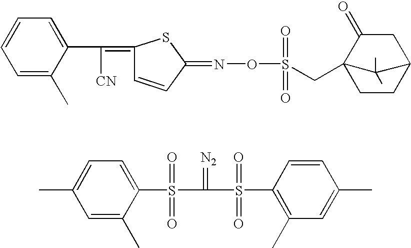

For instance, upon development, those resist components having low solubility/affinity to a developer deposit as foreign matter or debris in the spaces resulting from development of exposed areas and on the lines corresponding to unexposed areas.

The solubility of a photosensitive agent or photoacid generator has been a problem since the time when quinonediazide photosensitive agents were used for non-chemical amplification type positive resist materials. Illustrative problems include the solubility of photoacid generator in a resist solvent, the compatibility between a photoacid generator and a resin, the solubility in (or affinity to) a developer of photo-decomposed product and non-decomposed product (photoacid generator) after exposure and PEB, and the solubility in a remover solvent upon resist removal or peeling. If these solubilities are poor, there can arise problems including precipitation of photoacid generator during shelf storage, difficult filtration, uneven coating, striation, resist sensitivity anomalies, foreign matter on pattern/spaces after development, dissolution residues, and stains.

The photoacid generator for resist materials is required to have a fully high solubility (or compatibility) in resist solvents and resins, good storage stability, non-toxicity, ease of application, no foreign matter left after pattern formation by development or after resist removal, no footing of a pattern profile even on a basic organic antireflection film, PED stability, high resolution, and high sensitivity. Prior art photoacid generators, especially O-arylsulfonyloxime compound base photoacid generators do not satisfy all these requirements.

In the recent stage when the pattern feature of integrated circuits becomes more miniaturized, more stringent requirements are imposed on the problems of resolution, pattern profile on a basic organic antireflection film, and foreign matter after development and peeling.

### SUMMARY OF THE INVENTION

An object of the present invention is to provide a photoacid generator suitable for use in a resist composition, especially a chemically amplified positive resist composition, such that the resist composition overcomes the above-discussed problems and especially, leaves minimized foreign matter after coating, development and peeling and offers a well-defined pattern profile even on a basic organic antireflection film. Another object of the invention is to provide a resist composition comprising the photoacid generator, and a patterning process using the same.

We have found that a chemically amplified positive resist composition comprising an O-arylsulfonyloxime compound of the general formula (1) or (1a) or (1b), shown below, capable of generating 2,4,6-triisopropylbenzenesulfonic acid upon exposure to radiation as a photoacid generator possesses a number of great advantages including dissolution, storage stability, effective coating, minimized line width variation or shape degradation during long-term PED, minimized shape degradation, minimized foreign matter after coating, development and peeling, a well-defined pattern profile after development, and a high resolution enough for microfabrication, especially when processed by deep UV lithography.

The present invention provides a photoacid generator for chemically amplified positive resist compositions, having the general formula (1), (1a) or (1b).

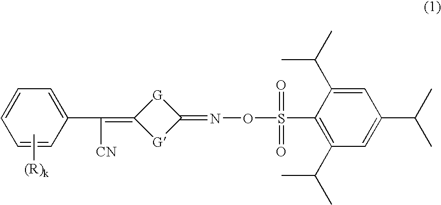

Herein G and G′ each are a sulfur atom or —CH═CH—, excluding the case where both G and G′ are sulfur atoms, R which may be the same or different is a hydrogen atom, fluorine atom, chlorine atom, or substituted or unsubstituted straight, branched or cyclic alkyl or alkoxy group of 1 to 4 carbon atoms, and k is an integer of 0 to 4.

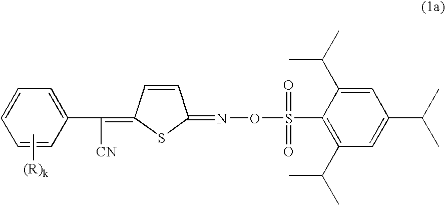

Herein R and k are as defined above.

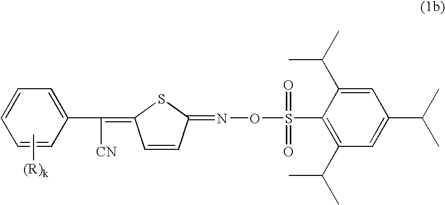

Herein R and k are as defined above.

In a second aspect, the invention provides a chemically amplified positive resist composition comprising (A) a resin which changes its solubility in an alkaline developer under the action of an acid and (B) the photoacid generator of formula (1), (1a) or (1c). The resist composition may further include (C) a compound capable of generating an acid upon exposure to radiation, other than component (B), (D) a basic compound, and (E) an organic acid derivative.

In one preferred embodiment, the resin (A) has such substituent groups having C—O—C linkages that the solubility in an alkaline developer changes as a result of scission of the C—O—C linkages under the action of an acid.

In another preferred embodiment, the resin (A) is a polymer containing phenolic hydroxyl groups in which hydrogen atoms of the phenolic hydroxyl groups are substituted with acid labile groups of one or more types in a proportion of more than 0 mol % to 80 mol % on the average of the entire hydrogen atoms of the phenolic hydroxyl groups, the polymer having a weight average molecular weight of 3,000 to 100,000.

In a further preferred embodiment, the resin (A) is a polymer comprising recurring units of the following general formula (2a):

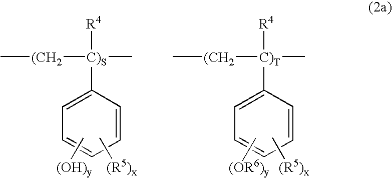

wherein R⁴ is hydrogen or methyl, R⁵ is a straight, branched or cyclic alkyl group of 1 to 8 carbon atoms, x is 0 or a positive integer, y is a positive integer, satisfying x+y≦5, R⁶ is an acid labile group, S and T are positive integers, satisfying 0<T/(S+T)≦0.8,

wherein the polymer contains units in which hydrogen atoms of phenolic hydroxyl groups are partially substituted with acid labile groups of one or more types, a proportion of the acid labile group-bearing units is on the average from more than 0 molt to 80 molt based on the entire polymer, and the polymer has a weight average molecular weight of 3,000 to 100,000.

In a further preferred embodiment, the resin (A) is a polymer comprising recurring units of the following general formula (2a′):

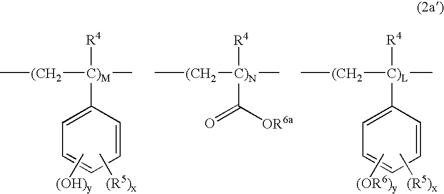

wherein R⁴ is hydrogen or methyl, R⁵ is a straight, branched or cyclic alkyl group of 1 to 8 carbon atoms, R⁶ is an acid labile group, R^{6a} is hydrogen or an acid labile group, at least some of R^{6a} being acid labile groups, x is 0 or a positive integer, y is a positive integer, satisfying x+y≦5, M and N are positive integers, L is 0 or a positive integer, satisfying 0<N/(M+N+L)≦0.5 and 0<(N+L)/(M+N+L)≦0.8,

wherein the polymer contains on the average from more than 0 molt to 50 molt of those units based on acrylate and methacrylate, and also contains on the average from more than 0 molt to 80 molt of acid labile group-bearing units, based on the entire polymer, and the polymer has a weight average molecular weight of 3,000 to 100,000.

In a further preferred embodiment, the resin (A) is a polymer comprising recurring units of the following general formula (2a″):

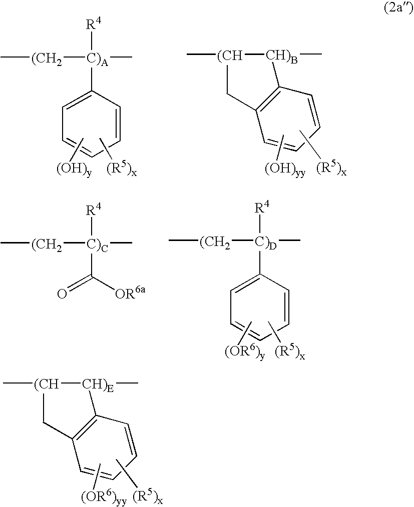

wherein R⁴ is hydrogen or methyl, R⁵ is a straight, branched or cyclic alkyl group of 1 to 8 carbon atoms, R⁶ is an acid labile group, R^{6a} is hydrogen or an acid labile group, at least some of R^{6a} being acid labile groups, x is 0 or a positive integer, y is a positive integer, satisfying x+y≦5, yy is 0 or a positive integer, satisfying x+yy≦4, A and B are positive integers, C, D and E each are 0 or a positive integer, satisfying 0<(B+E)/(A+B+C+D+E)≦0.5 and 0<(C+D+E)/(A+B+C+D+E)≦0.8,

wherein the polymer contains on the average from more than 0 mol % to 50 mol % of those units based on indene and/or substituted indene, and also contains on the average from more than 0 mol % to 80 mol % of acid labile group-bearing units, based on the entire polymer, and the polymer has a weight average molecular weight of 3,000 to 100,000.

In the foregoing preferred embodiments, the acid labile group is preferably selected from the class consisting of groups of the following general formulae (4) to (7), tertiary alkyl groups of 4 to 20 carbon atoms, trialkylsilyl groups whose alkyl moieties each have 1 to 6 carbon atoms, oxoalkyl groups of 4 to 20 carbon atoms, and aryl-substituted alkyl groups of 7 to 20 carbon atoms.

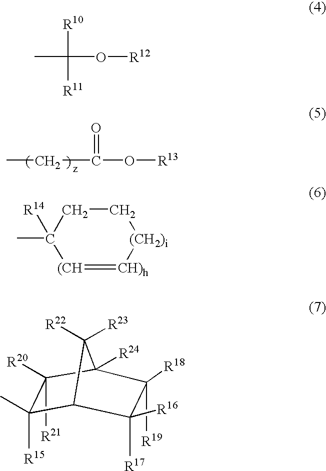

Herein R¹⁰ and R¹¹ each are hydrogen or a straight, branched or cyclic alkyl group having 1 to 18 carbon atoms, and R¹² is a monovalent hydrocarbon group of 1 to 18 carbon atoms which may contain a heteroatom, a pair of R¹⁰ and R¹¹, R¹⁰ and R², or R¹¹, and R¹² may together form a ring, with the proviso that R¹⁰, R¹¹, and R¹² each are a straight or branched alkylene of 1 to 18 carbon atoms when they form a ring; R¹³ is a tertiary alkyl group of 4 to 20 carbon atoms, a trialkysilyl group whose alkyl moieties each have 1 to 6 carbon atoms, an oxoalkyl group of 4 to 20 carbon atoms, or a group of the formula (4), z is an integer of 0 to 6; R¹⁴ is a straight, branched or cyclic alkyl group of 1 to 8 carbon atoms or an aryl group of 6 to 20 carbon atoms which may be substituted, h is 0 or 1, i is 0, 1, 2 or 3, satisfying 2h+i=2 or 3; R¹⁵ is a straight, branched or cyclic alkyl group of 1 to 8 carbon atoms or an aryl group of 6 to 20 carbon atoms which may be substituted, R¹⁶ to R²⁵ are each independently hydrogen or a monovalent hydrocarbon group of 1 to 15 carbon atoms which may contain a heteroatom, any two of R¹⁶ to R²⁵, taken together, may form a ring, each of the ring-forming two of R¹⁶ to R²⁵ is a divalent hydrocarbon group of 1 to 15 carbon atoms which may contain a heteroatom, or two of R¹⁶ to R²⁵ which are attached to adjoining carbon atoms may bond together directly to form a double bond.

Preferably the resist composition contains a propylene glycol alkyl ether acetate and/or an alkyl lactate as a solvent.

In a third aspect, the invention provides a process for forming a pattern, comprising the steps of applying the resist composition defined above onto a substrate to form a coating; heat treating the coating and exposing the coating to high energy radiation with a wavelength of up to 300 nm or electron beam through a photomask; optionally heat treating the exposed coating, and developing the coating with a developer.

### DESCRIPTION OF THE PREFERRED EMBODIMENTS

Photoacid Generator

In the first aspect, the present invention provides a photoacid generator having a 2,4,6-triisopropylbenzenesulfonyl group for use in chemically amplified positive resist compositions, represented by the general formula (1) or formula (1a) or (1b).

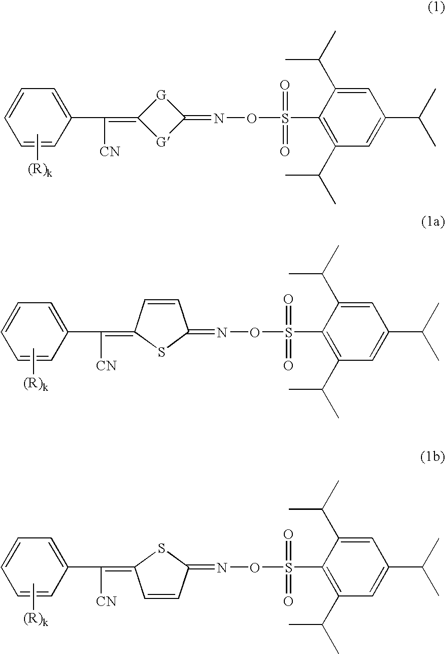

Herein, G, G′, R and k are as defined above.

In formula (1), each of G and G′ is a sulfur atom or —CH═CH—, excluding the case where both G and G′ are sulfur atoms.

In formula (1), (1a) or (1b), R which may be the same or different is a hydrogen atom, a fluorine atom, a chlorine atom, or a substituted or unsubstituted, straight, branched or cyclic alkyl or alkoxy group of 1 to 4 carbon atoms, for example, hydrogen, chlorine, fluorine, methyl, ethyl, n-ropyl, sec-propyl, cyclopropyl, n-butyl, sec-butyl, iso-utyl, tert-butyl, methoxy, ethoxy, n-propyloxy, sec-ropyloxy, n-butyloxy, sec-butyloxy, iso-butyloxy, and tert-butyloxy groups. Of these, hydrogen, chlorine, methyl, and methoxy groups are preferred, with hydrogen and methyl being more preferred. The subscript k is an integer of 0 to 4. The substitution position is not critical.

In the O-arylsulfonyloxime compounds of formulae (1), (1a) and (1b), the oxime skeleton is not critical. Preferred are oxime structures as found in well-known O-lkylsulfonyloxime compounds, especially in the compounds described in the above-referred patent JP-A 2002-508774.

The O-arylsulfonyloxime compounds can be synthesized by the following process although the synthesis process is not limited thereto.

The starting oxime compounds may be commercially available products or compounds synthesized as described in the literature (e.g., JP-A 2002-508774 and R. B. Davis et al., J. Org. Chem., 26, 4270, 1961). More preferably, as described in JP-A 2002-508774, a substituted phenylacetonitrile compound is reacted with 2-nitrothiophene or nitrobenzene in an alcohol solvent under basic conditions to form an oxime compound of the formula shown below. Although the compound obtained from 2-nitrothiophene includes geometrical isomers, the product is a single compound as analyzed by nuclear magnetic resonance spectroscopy.

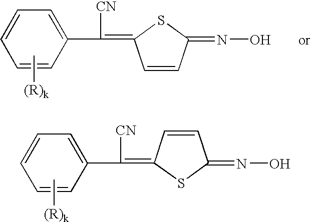

Though its structure has not been identified, the oxime compound synthesized according to the above formulation is desirably used as a reactant in the subsequent process.

The target O-sulfonyloxime compound is preferably prepared by dissolving the above oxime compound and commercially available 2,4,6-triisopropylbenzenesulfonyl halide or sulfonic acid anhydride in a solvent such as THF or CH₂Cl₂ and effecting reaction under basic conditions. Also preferably, the reaction may be effected in a basic solvent such as pyridine.

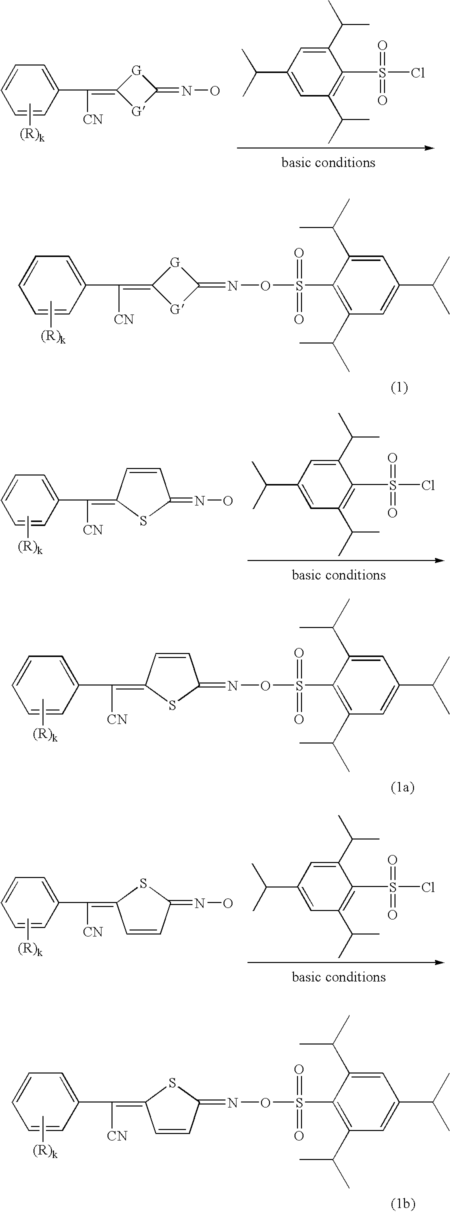

(G, G′, R and k are as defined above.)

While the substituents on the O-arylsulfonyloxime compounds having the formulae (1), (1a) and (1b) according to the invention are as defined above, preferred examples of the compounds are described below.

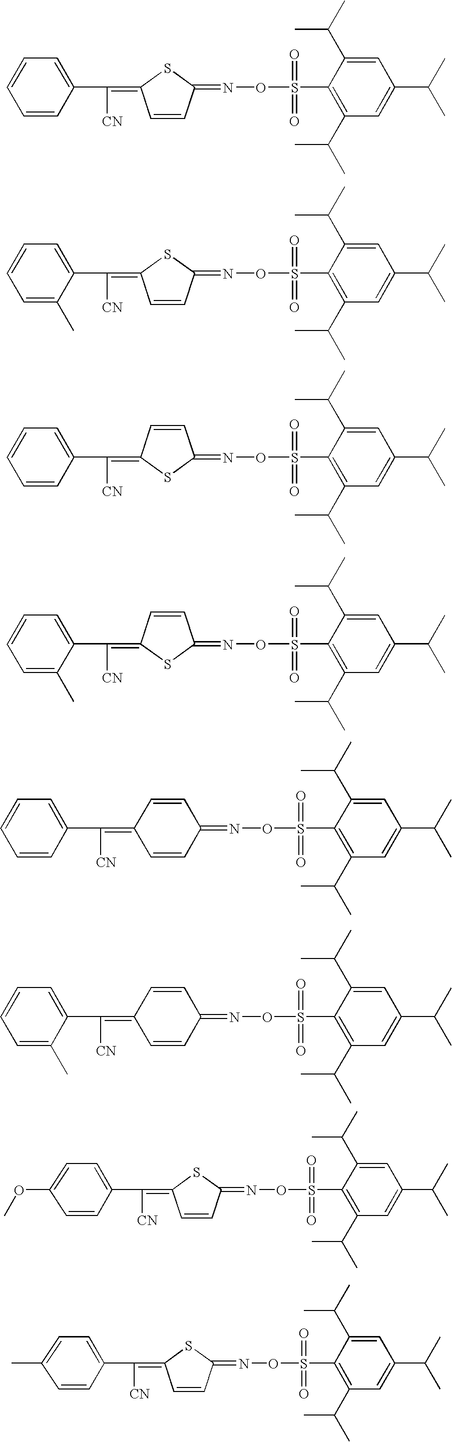

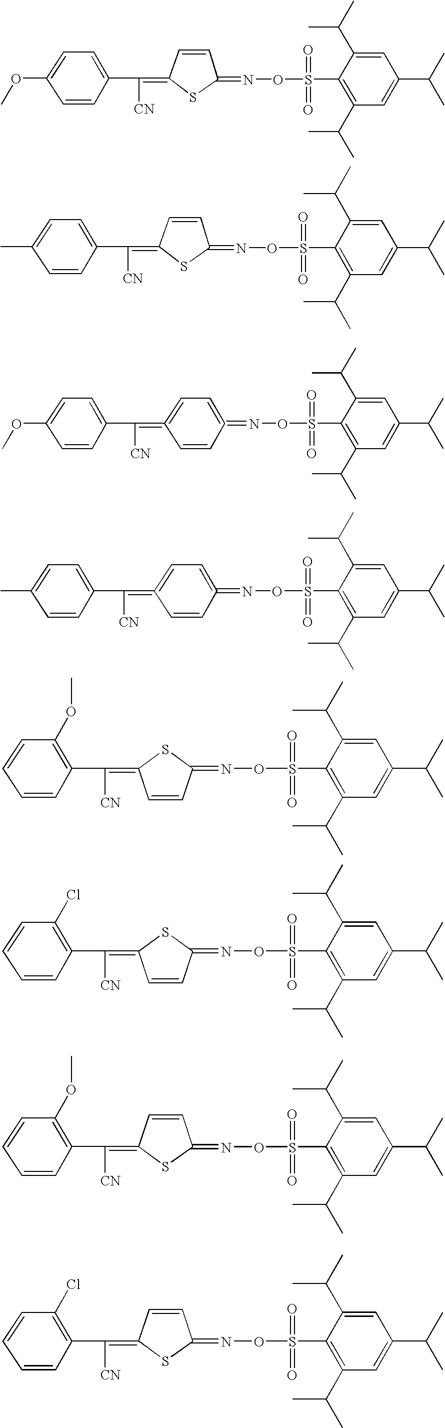

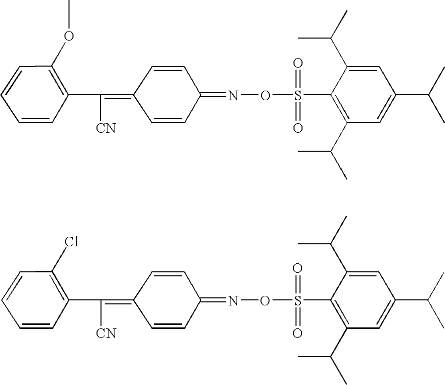

Resist Compositions

In the second aspect, the present invention provides a chemically amplified positive resist composition comprising a photoacid generator of the formula (1), (1a) or (1b), the composition being sensitive to such radiation as ultraviolet radiation, deep ultraviolet radiation, electron beams, x-rays, excimer laser beams, gamma-rays or synchrotron radiation and suitable for the microfabrication of integrated circuits.

The resist compositions of the invention include a variety of embodiments:

1) a chemically amplified positive working resist composition comprising (A) a resin which changes its solubility in an alkaline developer under the action of an acid, (B) the photoacid generator of formula (1), (1a) or (1b), and (F) an organic solvent;

2) a chemically amplified positive working resist composition of 1) further comprising (C) a photoacid generator capable of generating an acid upon exposure to radiation other than component (B);

3) a chemically amplified positive working resist composition of 1) or 2) further comprising (D) a basic compound;

4) a chemically amplified positive working resist composition of 1) to 3) further comprising (E) an organic acid derivative; and

5) a chemically amplified positive working resist composition of 1) to 4) further comprising (G) a compound with a molecular weight of up to 3,000 which changes its solubility in an alkaline developer under the action of an acid; but not limited thereto.

Now the respective components are described in detail.

Component (A)

Component (A) is a resin which changes its solubility in an alkaline developer solution under the action of an acid. It is preferably, though not limited thereto, an alkali-soluble resin having phenolic hydroxyl and/or carboxyl groups in which some or all of the phenolic hydroxyl and/or carboxyl groups are protected with acid-labile protective groups having a C—O—C linkage.

The alkali-soluble resins having phenolic hydroxyl and/or carboxyl groups include homopolymers and copolymers of p-hydroxystyrene, m-hydroxystyrene, α-methyl-p-hydroxystyrene, 4-hydroxy-2-methylstyrene, 4-hydroxy-3-methylstyrene, hydroxyindene, methacrylic acid and acrylic acid, and such copolymers having a carboxylic derivative or diphenyl ethylene introduced at their terminus.

Also included are copolymers in which units free of alkali-soluble sites such as styrene, a-methylstyrene, acrylate, methacrylate, hydrogenated hydroxystyrene, maleic anhydride, maleimide, substituted or unsubstituted indene are introduced in addition to the above-described units in such a proportion that the solubility in an alkaline developer may not be extremely reduced. Substituents on the acrylates and methacrylates may be any of the substituents which do not undergo acidolysis. Exemplary substituents are straight, branched or cyclic C₁₋₈ alkyl groups and aromatic groups such as aryl groups, but not limited thereto.

Examples of the alkali-soluble resins or polymers are given below. Examples include poly(p-hydroxystyrene), poly(m-hydroxystyrene), poly(4-hydroxy-2-methylstyrene), poly(4-hydroxy-3-methylstyrene), poly(α-methyl-p-hydroxystyrene), partially hydrogenated p-hydroxystyrene copolymers, p-hydroxystyrene-α-methyl-p-hydroxystyrene copolymers, p-hydroxystyrene-α-methylstyrene copolymers, p-hydroxystyrene-styrene copolymers, p-hydroxystyrene-m-hydroxystyrene copolymers, p-hydroxystyrene-styrene copolymers, p-hydroxystyrene-indene copolymers, p-hydroxystyrene-acrylic acid copolymers, p-hydroxystyrene-methacrylic acid copolymers, p-hydroxystyrene-methyl acrylate copolymers, p-hydroxystyrene-acrylic acid-methyl methacrylate copolymers, p-hydroxystyrene-methyl methacrylate copolymers, p-hydroxystyrene-methacrylic acid-methyl methacrylate copolymers, poly(methacrylic acid), poly(acrylic acid), acrylic acid-methyl acrylate copolymers, methacrylic acid-methyl methacrylate copolymers, acrylic acid-maleimide copolymers, methacrylic acid-maleimide copolymers, p-hydroxystyrene-acrylic acid-maleimide copolymers, and p-hydroxystyrene-methacrylic acid-maleimide copolymers, but are not limited to these combinations.

Preferred are poly(p-hydroxystyrene), partially hydrogenated p-hydroxystyrene copolymers, p-hydroxystyrene-styrene copolymers, p-hydroxystyrene-indene copolymers, p-hydroxystyrene-acrylic acid copolymers, and p-hydroxystyrene-methacrylic acid copolymers.

Alkali-soluble resins comprising units of the following formula (2), (2′) or (2″) are especially preferred.

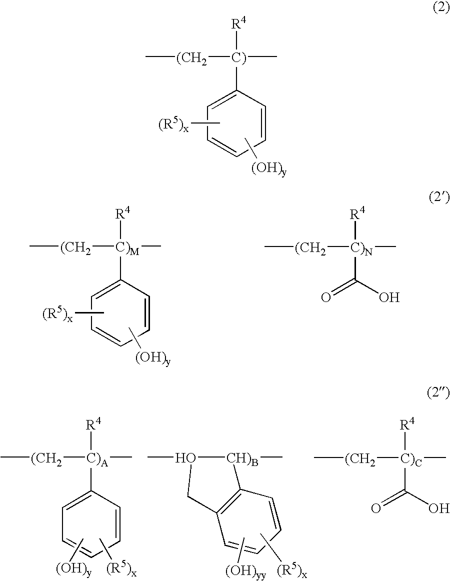

Herein R⁴ is hydrogen or methyl, R⁵ is a straight, branched or cyclic alkyl group of 1 to 8 carbon atoms, x is 0 or a positive integer, y is a positive integer, satisfying x+y≦5, M and N are positive integers, satisfying 0<N/(M+N)≦0.5, yy is 0 or a positive integer, satisfying x+yy≦4, and A and B are positive integers, and C is 0 or a positive integer, satisfying 0<B/(A+B+C)≦0.5.

The polymer of formula (2″) can be synthesized, for example, by effecting thermal polymerization of an acetoxystyrene monomer, a tertiary alkyl (meth)acrylate monomer and an indene monomer in an organic solvent in the presence of a radical initiator, and subjecting the resulting polymer to alkaline hydrolysis in an organic solvent for deblocking the acetoxy group, for thereby forming a ternary copolymer of hydroxystyrene, tertiary alkyl (meth)acrylate and indene. The organic solvent used during polymerization is exemplified by toluene, benzene, tetrahydrofuran, diethyl ether and dioxane. Exemplary polymerization initiators include 2,2′-azobisisobutyronitrile, 2,2′-azobis(2,4-dimethylvaleronitrile), dimethyl-2,2-azobis(2-methylpropionate), benzoyl peroxide, and lauroyl peroxide. Polymerization is preferably effected while heating at 50 to 80° C. The reaction time is usually about 2 to 100 hours, preferably about 5 to 20 hours. Aqueous ammonia, triethylamine or the like may be used as the base for the alkaline hydrolysis. For the alkaline hydrolysis, the temperature is usually −20° C. to 100° C., preferably 0° C. to 60° C., and the time is about 0.2 to 100 hours, preferably about 0.5 to 20 hours.

Also included are polymers having the dendritic or hyperbranched polymer structure of formula (2″′) below.

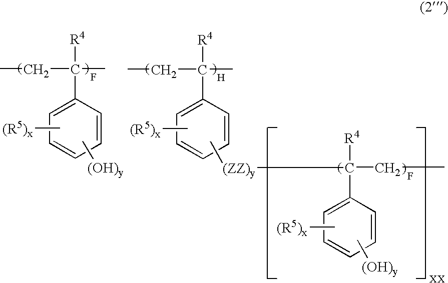

Herein ZZ is a divalent organic group selected from among CH₂, CH(OH), CR⁵(OH), C═O and C(OR⁵)(OH) or a trivalent organic group represented by —C(OH)═. Subscript F, which may be identical or different, is a positive integer, and H is a positive integer, satisfying 0.001≦H/(H+F)≦0.1, and XX is 1 or 2. R⁴, R⁵, x and y are as defined above.

The dendritic or hyperbranched polymer of phenol derivative can be synthesized by effecting living anion polymerization of a polymerizable monomer such as 4-tert-butoxystyrene and reacting a branching monomer such as chloromethylstyrene as appropriate during the living anion polymerization.

More particularly, living anion polymerization is started using a polymerizable monomer such as 4-tert-butoxystyrene. After a predetermined amount has been polymerized, a branching monomer such as chloromethylstyrene is introduced and reacted with the intermediate. Then the polymerizable monomer such as 4-tert-butoxystyrene and/or the branching monomer such as chloromethylstyrene is added again for polymerization. This operation is repeated many times until a desired dendritic or hyperbranched polymer is obtained. If necessary, the protective groups used to enable living polymerization are deblocked, yielding a dendritic or hyperbranched polymer of phenol derivative.

Examples of the branching monomer are given below.

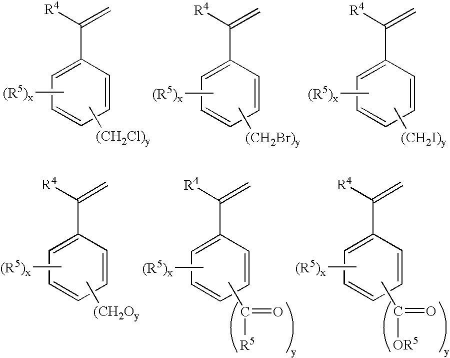

R⁴, R⁵, x and y are as defined above.

Illustrative examples of the dendritic or hyperbranched polymer are those having recurring units of the following approximate formulas (8) to (12).

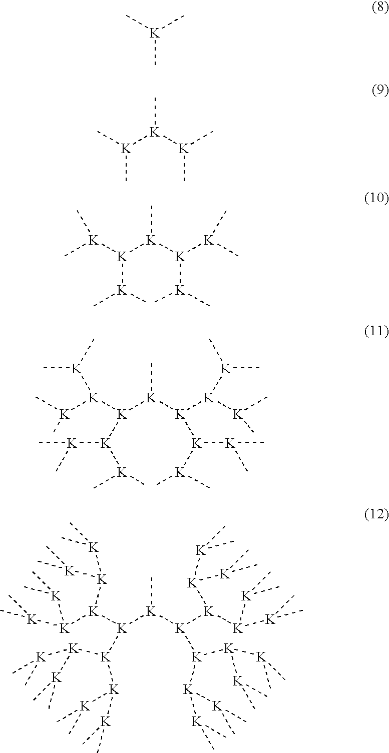

Herein, broken lines ( - - - ) represent polymer chains derived from the phenol derivative monomer, and K represents units derived from the branching monomer. The number of broken line segments between K and K is depicted merely for the sake of convenience, independent of the number of recurring units in the polymer chain included between K and K.

The dendritic or hyperbranched polymer of a phenol derivative is prepared by effecting living polymerization of the phenol derivative, reacting with a compound having a polymerizable moiety and a terminating moiety and proceeding further polymerization. By repeating this operation desired times, a dendritic or hyperbranched polymer of phenol derivative can be synthesized. The living polymerization may be effected by any desired technique although living anion polymerization is preferred because of ease of control. For the detail of synthesis, reference is made to JP-A 2000-344836.

The alkali-soluble resins or polymers should preferably have a weight average molecular weight (Mw) of 3,000 to 100,000. Many polymers with Mw of less than 3,000 do not perform well and are poor in heat resistance and film formation. Many polymers with Mw of more than 100,000 give rise to a problem with respect to dissolution in the resist solvent and developer. The polymer should also preferably have a dispersity (Mw/Mn) of up to 3.5, and more preferably up to 1.5. With a dispersity of more than 3.5, resolution is low in many cases. Although the preparation method is not critical, a poly(p-hydroxystyrene) or similar polymer with a low dispersity or narrow dispersion can be synthesized by living anion polymerization.

In the resist composition of the invention, a resin having such substituent groups with C—O—C linkages (acid labile groups) that the solubility in an alkaline developer changes as a result of severing of the C—O—C linkages under the action of an acid, especially an alkali-soluble resin as mentioned above is preferably used as component (A). Especially preferred is a polymer comprising recurring units of the above formula (2) and containing phenolic hydroxyl groups in which hydrogen atoms of the phenolic hydroxyl groups are substituted with acid labile groups of one or more types in a proportion of more than 0 mol % to 80 mol % on the average of the entire hydrogen atoms of the phenolic hydroxyl group, the polymer having a weight average molecular weight of 3,000 to 100,000.

Also preferred is a polymer comprising recurring units of the above formula (2′), that is, a copolymer comprising p-hydroxystyrene and/or α-methyl-p-hydroxystyrene and acrylic acid and/or methacrylic acid, wherein some of the hydrogen atoms of the carboxyl groups of acrylic acid and/or methacrylic acid are substituted with acid labile groups of one or more types, and the units based on acrylate and/or methacrylate are contained in a proportion of more than 0 mol % to 50 mol %, on the average, of the copolymer, and wherein some of the hydrogen atoms of the phenolic hydroxyl groups of p-hydroxystyrene and/or α-methyl-p-hydroxystyrene may be substituted with acid labile groups of one or more types. In the preferred copolymer, the units based on acrylate and/or methacrylate having acid labile groups substituted thereon and the units based on p-hydroxystyrene and/or α-methyl-p-hydroxystyrene having acid labile groups substituted thereon are contained in a proportion of more than 0 mol % to 80 mol %, on the average, of the copolymer.

Alternatively, a polymer comprising recurring units of the above formula (2″), that is, a copolymer comprising p-hydroxystyrene and/or α-methyl-p-hydroxystyrene and substituted and/or unsubstituted indene, is preferred wherein some of the hydrogen atoms of the phenolic hydroxyl groups of p-hydroxystyrene and/or α-methyl-p-hydroxystyrene are substituted with acid labile groups of one or more types, and/or some of the hydrogen atoms of the carboxyl groups of acrylic acid and/or methacrylic acid are substituted with acid labile groups of one or more types. Where the substituted indene has hydroxyl groups, some of the hydrogen atoms of these hydroxyl groups may be substituted with acid labile groups of one or more types. In the preferred copolymer, the units based on p-hydroxystyrene and/or α-methyl-p-hydroxystyrene having acid labile groups substituted thereon, the units based on acrylic acid and/or methacrylic acid having acid labile groups substituted thereon, and the units based on indene having acid labile groups substituted thereon are contained in a proportion of more than 0 mol % to 80 mol %, on the average, of the copolymer.

Exemplary and preferred such polymers are polymers or high molecular weight compounds comprising recurring units represented by the following general formula (2a), (2a′) or (2a″) and having a weight average molecular weight of 3,000 to 100,000.

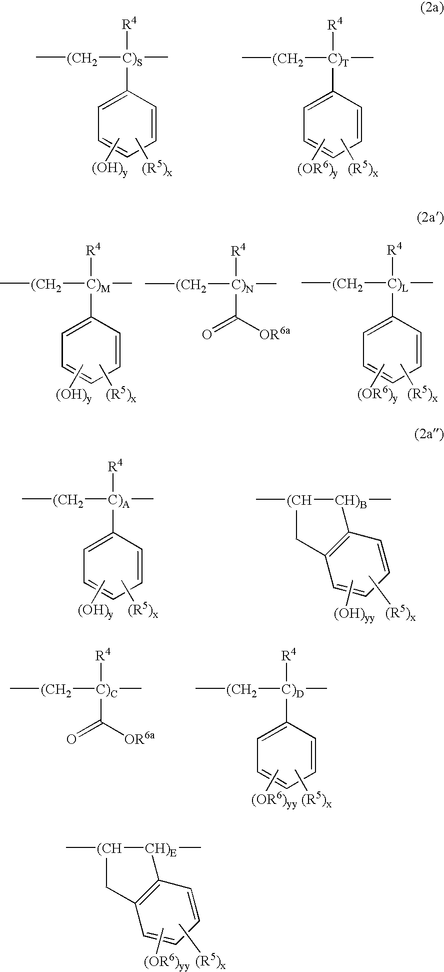

Herein, R⁴ is hydrogen or methyl. R⁵ is a straight, branched or cyclic alkyl group of 1 to 8 carbon atoms. Letter x is 0 or a positive integer, and y is a positive integer, satisfying x+y≦5. R⁶ is an acid labile group. S and T are positive integers, satisfying 0<T/(S+T)≦0.8. R^{6a} is hydrogen or an acid labile group, at least some of the R^{6a} groups are acid labile groups. M and N are positive integers, L is 0 or a positive integer, satisfying 0<N/(M+N+L)≦0.5 and 0<(N+L)/(M+N+L)≦0.8. The letter yy is 0 or a positive integer, satisfying x+yy<4. A and B are positive integers, C, D and E each are 0 or a positive integer, satisfying 0<(B+E)/(A+B+C+D+E)≦0.5 and 0<(C+D+E)/(A+B+C+D+E)≦0.8.

R⁵ stands for straight, branched or cyclic C₁₋₈ alkyl groups, for example, methyl, ethyl, propyl, isopropyl, n-butyl, isobutyl, tert-butyl, cyclohexyl and cyclopentyl.

The acid labile groups are selected from a variety of such groups. The preferred acid labile groups are groups of the following general formulae (4) to (7), tertiary alkyl groups of 4 to 20 carbon atoms, preferably 4 to 15 carbon atoms, trialkylsilyl groups whose alkyl groups each have 1 to 6 carbon atoms, oxoalkyl groups of 4 to 20 carbon atoms, or aryl-substituted alkyl groups of 7 to 20 carbon atoms.

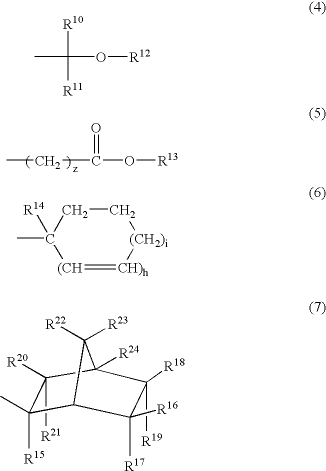

Herein R¹⁰ and R¹¹ are independently hydrogen or straight, branched or cyclic alkyl groups of 1 to 18 carbon atoms, preferably 1 to 10 carbon atoms, for example, methyl, ethyl, propyl, isopropyl, n-butyl, sec-butyl, tert-butyl, cyclopentyl, cyclohexyl, 2-ethylhexyl and n-octyl. R¹² is a monovalent hydrocarbon group of 1 to 18 carbon atoms, preferably 1 to 10 carbon atoms, which may have a hetero atom (e.g., oxygen atom), for example, straight, branched or cyclic alkyl groups, and such groups in which some hydrogen atoms are substituted with hydroxyl, alkoxy, oxo, amino or alkylamino groups. Illustrative examples of the substituted alkyl groups are given below.

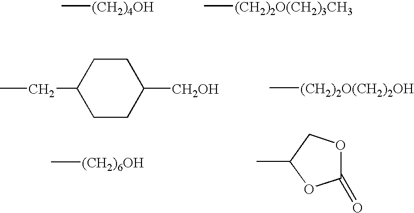

A pair of R¹⁰ and R¹¹, a pair of R¹⁰ and R¹², or a pair of R¹¹ and R¹², taken together, may form a ring. Each of R¹⁰, R¹¹ and R¹² is a straight or branched alkylene group of 1 to 18 carbon atoms, preferably 1 to 10 carbon atoms, when they form a ring.

R¹³ is a tertiary alkyl group of 4 to 20 carbon atoms, preferably 4 to 15 carbon atoms, a trialkylsilyl group whose alkyl groups each have 1 to 6 carbon atoms, an oxoalkyl group of 4 to 20 carbon atoms or a group of formula (4). Exemplary tertiary alkyl groups are tert-butyl, tert-amyl, 1,1-diethylpropyl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, 2-ethyl-2-adamantyl and 1-adamantyl-1-methylethyl. Exemplary trialkylsilyl groups are trimethylsilyl, triethylsilyl, and dimethyl-tert-butylsilyl. Exemplary oxoalkyl groups are 3-oxocyclohexyl, 4-methyl-2-oxooxan-4-yl, and 5-methyl-5-oxooxolan-4-yl. Letter z is an integer of 0 to 6.

R¹⁴ is a straight, branched or cyclic alkyl group of 1 to 8 carbon atoms or substituted or unsubstituted aryl group of 6 to 20 carbon atoms. Exemplary straight, branched or cyclic alkyl groups include methyl, ethyl, propyl, isopropyl, n-butyl, sec-butyl, tert-butyl, tert-amyl, n-pentyl, n-hexyl, cyclopentyl, cyclohexyl, cyclopentylmethyl, cyclopentylethyl, cyclohexylmethyl and cyclohexylethyl. Exemplary substituted or unsubstituted aryl groups include phenyl, methylphenyl, naphthyl, anthryl, phenanthryl, and pyrenyl. Letter h is equal to 0 or 1, i is equal to 0, 1, 2 or 3, satisfying 2h+i=2 or 3.

R¹⁵ is a straight, branched or cyclic alkyl group of 1 to 8 carbon atoms or substituted or unsubstituted aryl group of 6 to 20 carbon atoms, examples of which are as exemplified for R¹⁴. R¹⁶ to R²⁵ are independently hydrogen or monovalent hydrocarbon groups of 1 to 15 carbon atoms which may contain a hetero atom, for example, straight, branched or cyclic alkyl groups such as methyl, ethyl, propyl, isopropyl, n-butyl, sec-butyl, tert-butyl, tert-amyl, n-pentyl, n-hexyl, n-octyl, n-nonyl, n-decyl, cyclopentyl, cyclohexyl, cyclopentylmethyl, cyclopentylethyl, cyclopentylbutyl, cyclohexylmethyl, cyclohexylethyl, and cyclohexylbutyl, and substituted ones of these groups in which some hydrogen atoms are substituted with hydroxyl, alkoxy, carboxy, alkoxycarbonyl, oxo, amino, alkylamino, cyano, mercapto, alkylthio, and sulfo groups. Any two of R¹⁶ to R²⁵, for example, a pair of R¹⁶ and R¹⁷, a pair of R¹⁶ and R¹⁸, a pair of R¹⁷ and R¹⁹, a pair of R¹⁸ and R¹⁹, a pair of R²⁰ and R²¹, or a pair of R²² and R²³, taken together, may form a ring. When any two of R¹⁶ to R²⁵ form a ring, each is a divalent hydrocarbon group of 1 to 15 carbon atoms which may contain a hetero atom, examples of which are the above-exemplified monovalent hydrocarbon groups with one hydrogen atom eliminated. Also, two of R¹⁶ to R²⁵ which are attached to adjacent carbon atoms (for example, a pair of R¹⁶ and R¹⁸, a pair of R¹⁸ and R²⁴, or a pair of R²² and R²⁴) may directly bond together to form a double bond.

Of the acid labile groups of formula (4), illustrative examples of the straight or branched groups are given below.

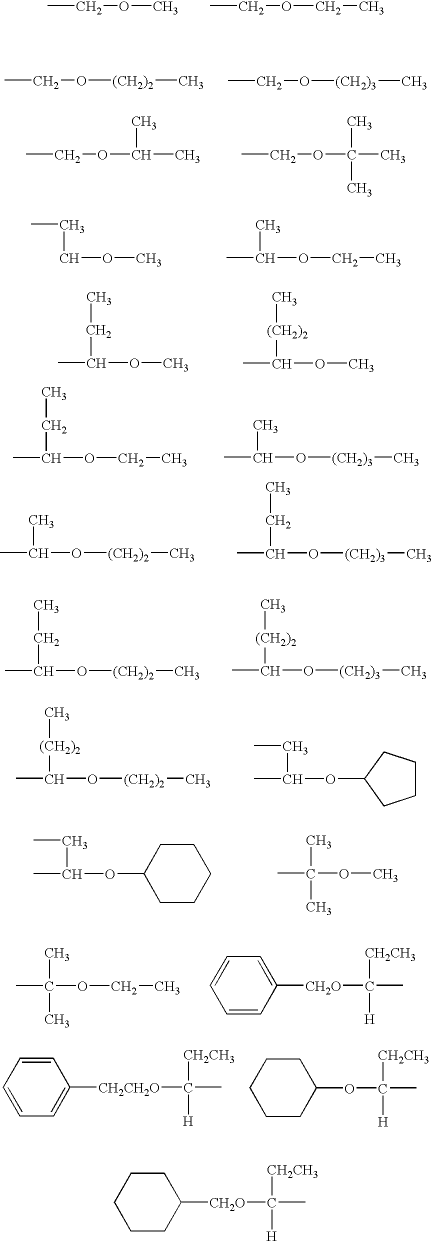

Of the acid labile groups of formula (4), illustrative examples of the cyclic groups include tetrahydrofuran-2-yl, 2-methyltetrahydrofuran-2-yl, tetrahydropyran-2-yl and 2-methyltetrahydropyran-2-yl.

Illustrative examples of the acid labile groups of formula (5) include tert-butoxycarbonyl, tert-butoxycarbonylmethyl, tert-amyloxycarbonyl, tert-amyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl.

Illustrative examples of the acid labile groups of formula (6) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, 3-ethyl-1-cyclohexen-3-yl, and 1-cyclohexyl-cyclopentyl.

Illustrative examples of the acid labile groups of formula (7) are given below.

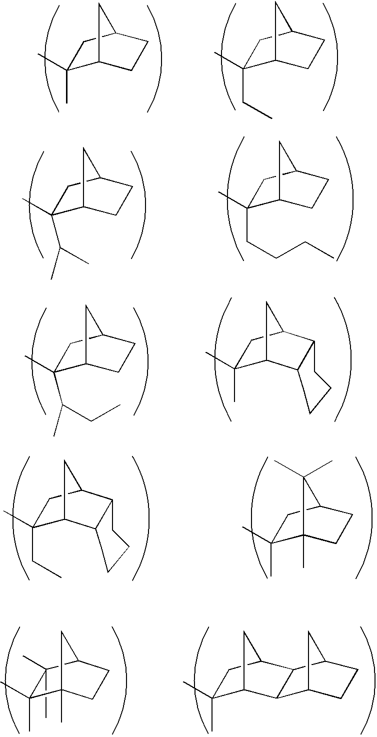

Exemplary of the tertiary alkyl group of 4 to 20 carbon atoms, preferably 4 to 15 carbon atoms, are tert-butyl, tert-amyl, 3-ethyl-3-pentyl and dimethylbenzyl.

Exemplary of the trialkylsilyl groups whose alkyl groups each have 1 to 6 carbon atoms are trimethylsilyl, triethylsilyl, and tert-butyldimethylsilyl.

Exemplary of the oxoalkyl groups of 4 to 20 carbon atoms are 3-oxocyclohexyl and groups represented by the following formulae.

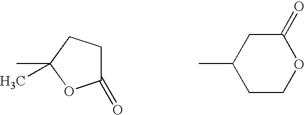

Exemplary of the aryl-substituted alkyl groups of 7 to 20 carbon atoms are benzyl, methylbenzyl, dimethylbenzyl, diphenylmethyl, and 1,1-diphenylethyl.

In the resist composition comprising the O-arylsulfonyloxime compound as a photoacid generator, the resin (A) which changes its solubility in an alkaline developer under the action of an acid may be the polymer of formula (2) or (2′), (2″) or (2″′) in which some of the hydrogen atoms of the phenolic hydroxyl groups are crosslinked within a molecule and/or between molecules, in a proportion of more than 0 mol % to 50 mol %, on the average, of the entire phenolic hydroxyl groups on the polymer, with crosslinking groups having C—O—C linkages represented by the following general formula (3). With respect to illustrative examples and synthesis of polymers crosslinked with acid labile groups, reference should be made to JP-A 11-190904.

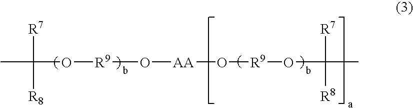

Herein, each of R⁷ and R⁸ is hydrogen or a straight, branched or cyclic alkyl group of 1 to 8 carbon atoms, or R⁷ and R⁸, taken together, may form a ring, and each of R¹ and R⁸ is a straight or branched alkylene group of 1 to 8 carbon atoms when they form a ring. R⁹ is a straight, branched or cyclic alkylene group of 1 to 10 carbon atoms. Letter “b” is 0 or an integer of 1 to 10. AA is an a-valent aliphatic or alicyclic saturated hydrocarbon group, aromatic hydrocarbon group or heterocyclic group of 1 to 50 carbon atoms, which may be separated by a hetero atom and in which some of the hydrogen atom attached to carbon atoms may be substituted with hydroxyl, carboxyl, carbonyl or halogen. Letter “a” is an integer of 1 to 7.

Preferably in formula (3), R⁷ is methyl, R⁸ is hydrogen, a is 1, b is 0, and AA is ethylene, 1,4-butylene or 1,4-cyclohexylene.

It is noted that these polymers which are crosslinked within the molecule or between molecules with crosslinking groups having C—O—C linkages can be synthesized by reacting a corresponding non-crosslinked polymer with an alkenyl ether in the presence of an acid catalyst in a conventional manner.

If decomposition of other acid labile groups proceeds under acid catalyst conditions, the end product can be obtained by once reacting the alkenyl ether with hydrochloric acid or the like for conversion to a halogenated alkyl ether and reacting it with the polymer under basic conditions in a conventional manner.

Illustrative, non-limiting, examples of the alkenyl ether include ethylene glycol divinyl ether, triethylene glycol divinyl ether, 1,2-propanediol divinyl ether, 1,3-propanediol divinyl ether, 1,3-butanediol divinyl ether, 1,4-butanediol divinyl ether, neopentyl glycol divinyl ether, trimethylolpropane trivinyl ether, trimethylolethane trivinyl ether, hexanediol divinyl ether, and 1,4-cyclohexanediol divinyl ether.

In the chemical amplification type positive resist composition of the invention, the resin used as component (A) is as described above while the preferred acid labile groups to be substituted for phenolic hydroxyl groups are 1-ethoxyethyl, 1-ethoxypropyl, tetrahydrofuranyl, tetrahydropyranyl, tert-butyl, tert-amyl, 1-ethylcyclohexyloxycarbonylmethyl, tert-butoxycarbonyl, tert-butoxycarbonylmethyl, and substituents of formula (3) wherein R⁷ is methyl, R⁸ is hydrogen, a is 1, b is 0, and AA is ethylene, 1,4-butylene or 1,4-cyclohexylene. Also preferably, the hydrogen atoms of carboxyl groups of methacrylic acid or acrylic acid are protected with substituent groups as typified by tert-butyl, tert-amyl, 2-methyl-2-adamantyl, 2-ethyl-2-adamantyl, 1-ethylcyclopentyl, 1-ethylcyclohexyl, 1-cyclohexylcyclopentyl, 1-ethylnorbornyl, tetrahydrofuranyl and tetrahydropyranyl.

In a single polymer, these substituents may be incorporated alone or in admixture of two or more types. A blend of two or more polymers having substituents of different types is also acceptable.

The percent proportion of these substituents substituting for phenol and carboxyl groups in the polymer is not critical. Preferably the percent substitution is selected such that when a resist composition comprising the polymer is applied onto a substrate to form a coating, the unexposed area of the coating may have a dissolution rate of 0.01 to 10 Å/sec in a 2.38% tetramethylammonium hydroxide (TMAH) developer.

On use of a polymer containing a greater proportion of carboxyl groups which can reduce the alkali dissolution rate, the percent substitution must be increased or non-acid-decomposable substituents to be described later must be introduced.

When acid labile groups for intramolecular and/or intermolecular crosslinking are to be introduced, the percent proportion of crosslinking substituents is preferably up to 20 mol %, more preferably up to 10 mol %, on the average, based on the entire recurring units of the polymer. If the percent substitution of crosslinking substituents is too high, crosslinking results in a higher molecular weight which can adversely affect dissolution, stability and resolution. It is also preferred to further introduce another non-crosslinking acid labile group into the crosslinked polymer at a percent substitution of up to 10 mol % for adjusting the dissolution rate to fall within the above range.

In the case of poly(p-hydroxystyrene), the optimum percent substitution differs between a substituent having a strong dissolution inhibitory action such as a tert-butoxycarbonyl group and a substituent having a weak dissolution inhibitory action such as an acetal group although the overall percent substitution is preferably 10 to 40 mol %, more preferably 20 to 30 mol %, on the average, based on the entire recurring units of the polymer.

Polymers having such acid labile groups introduced therein should preferably have a weight average molecular weight (Mw) of 3,000 to 100,000. With a Mw of less than 3,000, polymers would perform poorly and often lack heat resistance and film formability. Polymers with a Mw of more than 100,000 would be less soluble in a developer and a resist solvent.

Where non-crosslinking acid labile groups are introduced, the polymer should preferably have a dispersity (Mw/Mn) of up to 3.5, preferably up to 1.5. A polymer with a dispersity of more than 3.5 often results in a low resolution. Where crosslinking acid labile groups are introduced, the starting alkali-soluble resin should preferably have a dispersity (Mw/Mn) of up to 1.5, and the dispersity is kept at 3 or lower even after protection with crosslinking acid labile groups. If the dispersity is higher than 3, dissolution, coating, storage stability and/or resolution is often poor.

To impart a certain function, suitable substituent groups may be introduced into some of the phenolic hydroxyl and carboxyl groups on the acid labile group-protected polymer. Exemplary are substituent groups for improving adhesion to the substrate, non-acid-labile groups for adjusting dissolution in an alkali developer, and substituent groups for improving etching resistance. Illustrative, non-limiting, substituent groups include 2-hydroxyethyl, 2-hydroxypropyl, methoxymethyl, methoxycarbonyl, ethoxycarbonyl, methoxycarbonylmethyl, ethoxycarbonylmethyl, 4-methyl-2-oxo-4-oxolanyl, 4-methyl-2-oxo-4-oxanyl, methyl, ethyl, propyl, n-butyl, sec-butyl, acetyl, pivaloyl, adamantyl, isoboronyl, and cyclohexyl.

In the resist composition of the invention, the above-described resin is added in any desired amount, and usually 65 to 99 parts by weight, preferably 65 to 98 parts by weight per 100 parts by weight of the solids in the composition. The term “solids” is used to encompass all components in the resist composition excluding the solvent.

With respect to component (B), illustrative examples of the photoacid generators of formulae (1), (1a) and (1b) are as described above.

In the chemical amplification resist composition, an appropriate amount of the photoacid generator added is from 0.1 part to 10 parts by weight, and preferably from 1 to 5 parts by weight, per 100 parts by weight of the solids in the composition. A less amount of the photoacid generator below the range fails to generate a sufficient amount of acid to deblock acid labile groups in the polymer. Too large amounts may excessively reduce the transmittance of resist film, failing to form a rectangular pattern, and give rise to problems of abnormal particles and deposits during resist storage. The photoacid generators may be used alone or in admixture of two or more.

Component (C)

In one preferred embodiment, the resist composition further contains (C) a compound capable of generating an acid upon exposure to high-energy radiation (UV, deep UV, electron beams, x-rays, excimer laser beams, gamma-rays or synchrotron radiation), that is, a second photoacid generator other than component (B). Suitable second photoacid generators include sulfonium salts, iodonium salts, sulfonyldiazomethane and N-sulfonyloxydicarboxyimide photoacid generators. Exemplary second photoacid generators are given below while they may be used alone or in admixture of two or more.

Sulfonium salts are salts of sulfonium cations with sulfonates. Exemplary sulfonium cations include triphenylsulfonium, (4-tert-butoxyphenyl)diphenylsulfonium, bis(4-tert-butoxyphenyl)phenylsulfonium, tris(4-tert-butoxyphenyl)sulfonium, (3-tert-butoxyphenyl)diphenylsulfonium, bis(3-tert-butoxyphenyl)phenylsulfonium, tris(3-tert-butoxyphenyl)sulfonium, (3,4-di-tert-butoxyphenyl)diphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, (4-tert-butoxycarbonylmethyloxyphenyl)diphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, 2-naphthyldiphenylsulfonium, dimethyl-2-naphthylsulfonium, 4-hydroxyphenyldimethylsulfonium, 4-methoxyphenyldimethylsulfonium, trimethylsulfonium, 2-oxocyclohexylcyclohexylmethylsulfonium, trinaphthylsulfonium, tribenzylsulfonium, diphenylmethylsulfonium, dimethylphenylsulfonium, and 2-oxo-2-phenylethylthiacyclopentanium. Exemplary sulfonates include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, mesitylenesulfonate, 2,4,6-triisopropylbenzenesulfonate, toluenesulfonate, benzenesulfonate, 4-(4′-toluenesulfonyloxy)benzenesulfonate, naphthalenesulfonate, camphorsulfonate, octanesulfonate, dodecylbenzenesulfonate, butanesulfonate, and methanesulfonate. Sulfonium salts based on combination of the foregoing examples are included.

Iodinium salts are salts of iodonium cations with sulfonates. Exemplary iodinium cations are aryliodonium cations including diphenyliodinium, bis(4-tert-butylphenyl)iodonium, 4-tert-butoxyphenylphenyliodonium, and 4-methoxyphenylphenyliodonium. Exemplary sulfonates include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, mesitylenesulfonate, 2,4,6-triisopropylbenzenesulfonate, toluenesulfonate, benzenesulfonate, 4-(4-toluenesulfonyloxy)benzenesulfonate, naphthalenesulfonate, camphorsulfonate, octanesulfonate, dodecylbenzenesulfonate, butanesulfonate, and methanesulfonate. Iodonium salts based on combination of the foregoing examples are included.

Exemplary sulfonyldiazomethane compounds include bissulfonyldiazomethane compounds and sulfonyl-carbonyldiazomethane compounds such as bis(ethylsulfonyl)diazomethane, bis(1-methylpropylsulfonyl)diazomethane, bis(2-methylpropylsulfonyl)diazomethane, bis(1,1-dimethylethylsulfonyl)diazomethane, bis(cyclohexylsulfonyl)diazomethane, bis(perfluoroisopropylsulfonyl)diazomethane, bis(phenylsulfonyl)diazomethane, bis(4-methylphenylsulfonyl)diazomethane, bis(2,4-dimethylphenylsulfonyl)diazomethane, bis(4-acetyloxyphenylsulfonyl)diazomethane, bis(4-methanesulfonyloxyphenylsulfonyl)diazomethane, bis(4-(4-toluenesulfonyloxy)phenylsulfonyl)diazomethane, bis(2-naphthylsulfonyl)diazomethane, 4-methylphenylsulfonylbenzoyldiazomethane, tert-butylcarbonyl-4-methylphenylsulfonyldiazomethane, 2-naphthylsulfonylbenzoyldiazomethane, 4-methylphenylsulfonyl-2-naphthoyldiazomethane, methylsulfonylbenzoyldiazomethane, and tert-butoxycarbonyl-4-methylphenylsulfonyldiazomethane.

N-sulfonyloxydicarboxyimide photoacid generators include combinations of imide skeletons with sulfonates. Exemplary imide skeletons are succinimide, naphthalenedicarboxyimide, phthalimide, cyclohexyldicarboxyimide, 5-norbornene-2,3-dicarboxyimide, and 7-oxabicyclo[2.2.1]-5-heptene-2,3-dicarboxyimide. Exemplary sulfonates include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, mesitylenesulfonate, 2,4,6-triisopropylbenzenesulfonate, toluenesulfonate, benzenesulfonate, naphthalenesulfonate, camphorsulfonate, octanesulfonate, dodecylbenzenesulfonate, butanesulfonate, and methanesulfonate.

Benzoinsulfonate photoacid generators include benzoin tosylate, benzoin mesylate, and benzoin butanesulfonate.

Pyrogallol trisulfonate photoacid generators include pyrogallol, fluoroglycine, catechol, resorcinol, hydroquinone, in which all the hydroxyl groups are substituted with trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, methanesulfonate or the like.

Nitrobenzyl sulfonate photoacid generators include 2,4-dinitrobenzyl sulfonate, 2-nitrobenzyl sulfonate, and 2,6-dinitrobenzyl sulfonate, with exemplary sulfonates including trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, and methanesulfonate. Also useful are analogous nitrobenzyl sulfonate compounds in which the nitro group on the benzyl side is substituted with a trifluoromethyl group.

Sulfone photoacid generators include bis(phenylsulfonyl)methane, bis(4-methylphenylsulfonyl)methane, bis(2-naphthylsulfonyl)methane, 2,2-bis(phenylsulfonyl)propane, 2,2-bis(4-methylphenylsulfonyl)propane, 2,2-bis(2-naphthylsulfonyl)propane, 2-methyl-2-(p-toluenesulfonyl)propiophenone, 2-cyclohexylcarbonyl-2-(p-toluenesulfonyl)propane, and 2,4-dimethyl-2-(p-toluenesulfonyl)pentan-3-one.

Photoacid generators in the form of glyoxime derivatives are typically the compounds described in Japanese Patent No. 2,906,999 and JP-A 9-301948. Illustrative examples include bis-O-(p-toluenesulfonyl)-α-dimethylglyoxime, bis-O-(p-toluenesulfonyl)-α-diphenylglyoxime, bis-O-(p-toluenesulfonyl)-α-dicyclohexylglyoxime, bis-O-(p-toluenesulfonyl)-2,3-pentanedioneglyoxime, bis-O-(n-butanesulfonyl)-α-dimethylglyoxime, bis-O-(n-butanesulfonyl)-α-diphenylglyoxime, bis-O-(n-butanesulfonyl)-α-dicyclohexylglyoxime, bis-O-(methanesulfonyl)-α-dimethylglyoxime, bis-O-(trifluoromethanesulfonyl)-α-dimethylglyoxime, bis-O-(2,2,2-trifluoroethanesulfonyl)-α-dimethylglyoxime, bis-O-(10-camphorsulfonyl)-α-dimethylglyoxime, bis-O-(benzenesulfonyl)-α-dimethylglyoxime, bis-O-(p-fluorobenzenesulfonyl)-α-dimethylglyoxime, bis-O-(p-trifluoromethylbenzenesulfonyl)-α-dimethylglyoxime, bis-O-(xylenesulfonyl)-α-dimethylglyoxime, bis-O-(trifluoromethanesulfonyl)-nioxime, bis-O-(2,2,2-trifluoroethanesulfonyl)-nioxime, bis-O-(10-camphorsulfonyl)-nioxime, bis-O-(benzenesulfonyl)-nioxime, bis-O-(p-fluorobenzenesulfonyl)-nioxime, bis-O-(p-trifluoromethylbenzenesulfonyl)-nioxime, and bis-O-(xylenesulfonyl)-nioxime.

Also included are the oxime sulfonates described in JP-A 2002-508774, more particularly (5-(4-toluenesulfonyl)oxyimino-5H-thiophen-2-ylidene)phenyl-acetonitrile, (5-(10-camphorsulfonyl)oxyimino-5H-thiophen-2-ylidene)phenylacetonitrile, (5-n-octanesulfonyloxyimino-5H-thiophen-2-ylidene)phenylacetonitrile, (5-(4-toluenesulfonyl)oxyimino-5H-thiophen-2-ylidene)(2-methylphenyl)acetonitrile, (5-(10-camphorsulfonyl)oxyimino-5H-thiophen-2-ylidene)(2-methylphenyl)acetonitrile, and (5-n-octanesulfonyloxyimino-5H-thiophen-2-ylidene)(2-methylphenyl)acetonitrile.

Also included are the oxime sulfonates described in U.S. Pat. No. 6,261,738 and JP-A 2000-314956. Typical examples include 2,2,2-trifluoro-1-phenyl-ethanone oxime-O-methylsulfonate; 2,2,2-trifluoro-1-phenyl-ethanone oxime-O-(10-camphorylsulfonate); 2,2,2-trifluoro-1-phenyl-ethanone oxime-O-(4-methoxyphenylsulfonate); 2,2,2-trifluoro-1-phenyl-ethanone oxime-O-(1-naphthylsulfonate); 2,2,2-trifluoro-1-phenyl-ethanone oxime-O-(2-naphthylsulfonate); 2,2,2-trifluoro-1-phenyl-ethanone oxime-O-(2,4,6-trimethylphenylsulfonate); 2,2,2-trifluoro-1-(4-methylphenyl)-ethanone oxime-O-(10-camphorylsulfonate; 2,2,2-trifluoro-1-(4-methylphenyl)-ethanone oxime-O-(methylsulfonate); 2,2,2-trifluoro-1-(2-methylphenyl)-ethanone oxime-O-(10-camphorylsulfonate); 2,2,2-trifluoro-1-(2,4-dimethylphenyl)-ethanone oxime-O-(10-camphorylsulfonate); 2,2,2-trifluoro-1-(2,4-dimethylphenyl)-ethanone oxime-O-(1-naphthylsulfonate); 2,2,2-trifluoro-1-(2,4-dimethylphenyl)-ethanone oxime-O-(2-naphthylsulfonate); 2,2,2-trifluoro-1-(2,4,6-trimethylphenyl)-ethanone oxime-O-(10-camphorylsulfonate); 2,2,2-trifluoro-1-(2,4,6-trimethylphenyl)-ethanone oxime-O-(1-naphthylsulfonate); 2,2,2-trifluoro-1-(2,4,6-trimethylphenyl)-ethanone oxime-O-(2-naphthylsulfonate); 2.2.2-trifluoro-1-(4-methoxyphenyl)-ethanone oxime-O-methylsulfonate; 2,2,2-trifluoro-1-(4-methylthiophenyl)-ethanone oxime-O-methylsulfonate; 2,2,2-trifluoro-1-(3,4-dimethoxyphenyl)-ethanone oxime-O-methylsulfonate; 2,2,3,3,4,4,4-heptafluoro-1-phenyl-butanone oxime-O-(10-camphorylsulfonate); 2,2,2-trifluoro-1-(phenyl)-ethanone oxime-O-methylsulfonate; 2,2,2-trifluoro-1-(phenyl)-ethanone oxime-O-10-camphorylsulfonate; 2,2,2-trifluoro-1-(phenyl)-ethanone oxime-O-(4-methoxyphenyl)sulfonate; 2,2,2-trifluoro-1-(phenyl)-ethanone oxime-O-(1-naphthyl)sulfonate; 2,2,2-trifluoro-1-(phenyl)-ethanone oxime-O-(2-naphthyl)sulfonate; 2,2,2-trifluoro-1-(phenyl)-ethanone oxime-O-(2,4,6-trimethylphenyl)sulfonate; 2,2,2-trifluoro-1-(4-methylphenyl)-ethanone oxime-O-(10-camphoryl)sulfonate; 2,2,2-trifluoro-1-(4-methylphenyl)-ethanone oxime-O-methylsulfonate; 2,2,2-trifluoro-1-(2-methylphenyl)-ethanone oxime-O-(10-camphoryl)sulfonate; 2,2,2-trifluoro-1-(2,4-dimethylphenyl)-ethanone oxime-O-(1-naphthyl)sulfonate; 2,2,2-trifluoro-1-(2,4-dimethylphenyl)-ethanone oxime-O-(2-naphthyl)-sulfonate: 2,2,2-trifluoro-1-(2,4,6-trimethylphenyl)-ethanone oxime-O-(10-camphoryl)sulfonate; 2,2,2-trifluoro-1-(2,4,6-trimethylphenyl)-ethanone oxime-O-(1-naphthyl)sulfonate; 2,2,2-trifluoro-1-(2,4,6-trimethylphenyl)-ethanone oxime-O-(2-naphthyl)sulfonate; 2,2,2-trifluoro-1-(4-methoxyphenyl)-ethanone oxime-O-methylsulfonate; 2,2,2-trifluoro-1-(4-thiomethylphenyl)-ethanone oxime-O-methylsulfonate; 2,2,2-trifluoro-1-(3,4-dimethoxyphenyl)-ethanone oxime-O-methylsulfonate; 2,2,2-trifluoro-1-(4-methoxyphenyl)-ethanone oxime-O-(4-methylphenyl)sulfonate; 2,2,2-trifluoro-1-(4-methoxyphenyl)-ethanone oxime-O-(4-methoxyphenyl)sulfonate; 2,2,2-trifluoro-1-(4-methoxyphenyl)-ethanone oxime-O-(4-dodecylphenyl)sulfonate; 2,2,2-trifluoro-1-(4-methoxyphenyl)-ethanone oxime-O-octylsulfonate; 2,2,2-trifluoro-1-(4-thiomethylphenyl)-ethanone oxime-O-(4-methoxyphenyl)sulfonate; 2,2,2-trifluoro-1-(4-thiomethylphenyl)-ethanone oxime-O-(4-dodecylphenyl)sulfonate; 2,2,2-trifluoro-1-(4-thiomethylphenyl)-ethanone oxime-O-octylsulfonate; 2,2,2-trifluoro-1-(4-thiomethylphenyl)-ethanone oxime-O-(2-naphthyl)sulfonate; 2,2,2-trifluoro-1-(2-methylphenyl)-ethanone oxime-O-methylsulfonate; 2,2,2-trifluoro-1-(4-methylphenyl)ethanone oxime-O-phenylsulfonate; 2,2,2-trifluoro-1-(4-chlorophenyl)-ethanone oxime-O-phenylsulfonate; 2,2,3,3,4,4,4-heptafluoro-1-(phenyl)-butanone oxime-O-(10-camphoryl)sulfonate; 2,2,2-trifluoro-1-naphthyl-ethanone oxime-O-methylsulfonate; 2,2,2-trifluoro-2-naphthyl-ethanone oxime-O-methylsulfonate; 2,2,2-trifluoro-1-[4-benzylphenyl]-ethanone oxime-O-methylsulfonate; 2,2,2-trifluoro-1-[4-(phenyl-1,4-dioxa-but-1-yl)phenyl]-ethanone oxime-O-methylsulfonate; 2,2,2-trifluoro-1-naphthyl-ethanone oxime-O-propylsulfonate; 2,2,2-trifluoro-2-naphthyl-ethanone oxime-O-propylsulfonate; 2,2,2-trifluoro-1-[4-benzylphenyl]-ethanone oxime-O-propylsulfonate; 2,2,2-trifluoro-1-[4-methylsulfonylphenyl]-ethanone oxime-O-propylsulfonate; 1,3-bis[1-(4-phenoxyphenyl)-2,2,2-trifluoroethanone oxime-O-sulfonyl]phenyl; 2,2,2-trifluoro-1-[4-methylsulfonyloxyphenyl]-ethanone oxime-O-propylsulfonate; 2,2,2-trifluoro-1-[4-methylcarbonyloxyphenyl]-ethanone oxime-O-propylsulfonate; 2,2,2-trifluoro-1-[6H,7H-5,8-dioxonaphth-2-yl]-ethanone oxime-O-propylsulfonate; 2,2,2-trifluoro-1-[4-methoxycarbonylmethoxyphenyl]-ethanone oxime-O-propylsulfonate; 2,2,2-trifluoro-1-[4-(methoxycarbonyl)-(4-amino-1-oxa-pent-1-yl)-phenyl]-ethanone oxime-O-propylsulfonate; 2,2,2-trifluoro-1-[3,5-dimethyl-4-ethoxyphenyl]-ethanone oxime-O-propylsulfonate; 2,2,2-trifluoro-1-[4-benzyloxyphenyl]-ethanone oxime-O-propylsulfonate; 2,2,2-trifluoro-1-[2-thiophenyl]-ethanone oxime-O-propylsulfonate; and 2,2,2-trifluoro-1-[1-dioxa-thiophen-2-yl])-ethanone oxime-O-propylsulfonate.

Also included are the oxime sulfonates described in the preamble and detailed description sections of JP-A 9-95479 and JP-A 9-230588, more particularly α-(p-toluenesulfonyloxyimino)-phenylacetonitrile; α-(p-chlorobenzenesulfonyloxyimino)-phenylacetonitrile; α-(4-nitrobenzenesulfonyloxyimino)-phenylacetonitrile; α-(4-nitro-2-trifluoromethylbenzenesulfonyloxyimino)-phenylacetonitrile; α-(benzenesulfonyloxyimino)-4-chlorophenylacetonitrile; α-(benzenesulfonyloxyimino)-2,4-dichlorophenylacetonitrile; α-(benzenesulfonyloxyimino)-2,6-dichlorophenylacetonitrile; α-(benzenesulfonyloxyimino)-4-methoxyphenylacetonitrile; α-(2-chlorobenzenesulfonyloxyimino)-4-methoxyphenylacetonitrile; α-(benzenesulfonyloxyimino)-2-thienylacetonitrile; α-(4-dodecylbenzenesulfonyloxyimino)-phenylacetonitrile; α-[(4-toluenesulfonyloxyimino)-4-methoxyphenyl]acetonitrile; α-[(dodecylbenzenesulfonyloxyimino)-4-methoxyphenyl]acetonitrile; α-(tosyloxyimino)-3-thienylacetonitrile; α-(methylsulfonyloxyimino)-1-cyclopentenylacetonitrile; α-(ethylsulfonyloxyimino)-1-cyclopentenylacetonitrile; α-(isopropylsulfonyloxyimino)-1-cyclopentenylacetonitrile; α-(n-butylsulfonyloxyimino)-1-cyclopentenylacetonitrile; α-(ethylsulfonyloxyimino)-1-cyclohexenylacetonitrile; α-(isopropylsulfonyloxyimino)-1-cyclohexenylacetonitrile; and α-(n-butylsulfonyloxyimino)-1-cyclohexenylacetonitrile.

Bisoxime sulfonates are also useful as described in JP-A 9-208554, for example, bis(α-(4-toluenesulfonyloxy)imino)-p-phenylenediacetonitrile; bis(α-(benzenesulfonyloxy)imino)-p-phenylenediacetonitrile; bis(α-(methanesulfonyloxy)imino)-p-phenylenediacetonitrile; bis(α-(butanesulfonyloxy)imino)-p-phenylenediacetonitrile; bis(α-(10-camphorsulfonyloxy)imino)-p-phenylenediacetonitrile; bis(α-(trifluoromethanesulfonyloxy)imino)-p-phenylenediacetonitrile; bis(α-(4-methoxybenzenesulfonyloxy)imino)-p-phenylenediacetonitrile; bis(α-(4-toluenesulfonyloxy)imino)-m-phenylenediacetonitrile; bis(α-(benzenesulfonyloxy)imino)-m-phenylenediacetonitrile; bis(α-(methanesulfonyloxy)imino)-m-phenylenediacetonitrile; bis(α-(butanesulfonyloxy)imino)-m-phenylenediacetonitrile; bis(α-(10-camphorsulfonyloxy)imino)-m-phenylenediacetonitrile; bis(α-(trifluoromethanesulfonyloxy)imino)-m-phenylenediacetonitrile; and bis(α-(4-methoxybenzenesulfonyloxy)imino)-m-phenylenediacetonitrile.

Of these, preferred photoacid generators are sulfonium salts, bissulfonyldiazomethanes, and N-sulfonyloxydicarboxyimides. Illustrative preferred photoacid generators include triphenylsulfonium p-toluenesulfonate, triphenylsulfonium camphorsulfonate, triphenylsulfonium pentafluorobenzenesulfonate, triphenylsulfonium nonafluorobutanesulfonate, triphenylsulfonium 4-(4′-toluenesulfonyloxy)benzenesulfonate, triphenylsulfonium 2,4,6-triisopropylbenzenesulfonate, 4-tert-butoxyphenyldiphenylsulfonium p-toluenesulfonate, 4-tert-butoxyphenyldiphenylsulfonium camphorsulfonate, 4-tert-butoxyphenyldiphenylsulfonium 4-(4′-toluenesulfonyloxy)benzenesulfonate, tris(4-methylphenyl)sulfonium camphorsulfonate, tris(4-tert-butylphenyl)sulfonium camphorsulfonate, bis(tert-butylsulfonyl)diazomethane, bis(cyclohexylsulfonyl)diazomethane, bis(2,4-dimethylphenylsulfonyl)diazomethane, bis(4-tert-butylphenylsulfonyl)diazomethane, N-camphorsulfonyloxy-5-norbornene-2,3-carboxylic acid imide, and N-p-toluenesulfonyloxy-5-norbornene-2,3-carboxylic acid imide.

In the resist composition comprising the O-arylsulfonyloxime compound as the first photoacid generator (B) according to the invention, the second photoacid generator (C) may be used in any desired amount as long as it does not compromise the effects of the O-arylsulfonyloxime compound. An appropriate amount of the second photoacid generator (C) is 0 to 10 parts, and especially 0 to 5 parts by weight per 100 parts by weight of the solids in the composition. Too high a proportion of the second photoacid generator (C) may give rise to problems of degraded resolution and foreign matter upon development and resist film peeling. The second photoacid generators may be used alone or in admixture of two or more. The transmittance of the resist film can be controlled by using a (second) photoacid generator having a low transmittance at the exposure wavelength and adjusting the amount of the photoacid generator added.

In the resist composition comprising the O-arylsulfonyloxime compound as the photoacid generator according to the invention, there may be added a compound which is decomposed with an acid to generate an acid, that is, acid-propagating compound. For these compounds, reference should be made to J. Photopolym. Sci. and Tech., 8, 43-44, 45-46 (1995), and ibid., 9, 29-30 (1996).

Examples of the acid-propagating compound include tert-butyl-2-methyl-2-tosyloxymethyl acetoacetate and 2-phenyl-2-(2-tosyloxyethyl)-1,3-dioxolane, but are not limited thereto. Of well-known photoacid generators, many of those compounds having poor stability, especially poor thermal stability exhibit an acid-propagating compound-like behavior.

In the resist composition of the invention, an appropriate amount of the acid-propagating compound is up to 2 parts, and especially up to 1 part by weight per 100 parts by weight of the solids in the composition. Excessive amounts of the acid-propagating compound makes diffusion control difficult, leading to degradation of resolution and pattern configuration.

Component (D)

The basic compound used as component (D) is preferably a compound capable of suppressing the rate of diffusion when the acid generated by the photoacid generator diffuses within the resist film. The inclusion of this type of basic compound holds down the rate of acid diffusion within the resist film, resulting in better resolution. In addition, it suppresses changes in sensitivity following exposure and reduces substrate and environment dependence, as well as improving the exposure latitude and the pattern profile.

Examples of basic compounds include primary, secondary, and tertiary aliphatic amines, mixed amines, aromatic amines, heterocyclic amines, carboxyl group-bearing nitrogenous compounds, sulfonyl group-bearing nitrogenous compounds, hydroxyl group-bearing nitrogenous compounds, hydroxyphenyl group-bearing nitrogenous compounds, alcoholic nitrogenous compounds, amide derivatives, and imide derivatives.

Examples of suitable primary aliphatic amines include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, and tetraethylenepentamine. Examples of suitable secondary aliphatic amines include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and N,N-dimethyltetraethylenepentamine. Examples of suitable tertiary aliphatic amines include trimethylamine, triethylamine, tri-n-propylamine, triisopropylamine, tri-n-butylamine, triisobutylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, N,N,N′,N′-tetramethylmethylenediamine, N,N,N′,N′-tetramethylethylenediamine, and N,N,N′,N′-tetramethyltetraethylenepentamine.

Examples of suitable mixed amines include dimethylethylamine, methylethylpropylamine, benzylamine, phenethylamine, and benzyldimethylamine. Examples of suitable aromatic and heterocyclic amines include aniline derivatives (e.g., aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyltoluidine), diphenyl(p-tolyl)amine, methyldiphenylamine, triphenylamine, phenylenediamine, naphthylamine, diaminonaphthalene, pyrrole derivatives (e.g., pyrrole, 2H-pyrrole, 1-methylpyrrole, 2,4-dimethylpyrrole, 2,5-dimethylpyrrole, and N-methylpyrrole), oxazole derivatives (e.g., oxazole and isooxazole), thiazole derivatives (e.g., thiazole and isothiazole), imidazole derivatives (e.g., imidazole, 4-methylimidazole, and 4-methyl-2-phenylimidazole), pyrazole derivatives, furazan derivatives, pyrroline derivatives (e.g., pyrroline and 2-methyl-1-pyrroline), pyrrolidine derivatives (e.g., pyrrolidine, N-methylpyrrolidine, pyrrolidinone, and N-methylpyrrolidone), imidazoline derivatives, imidazolidine derivatives, pyridine derivatives (e.g., pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 1-methyl-2-pyridine, 4-pyrrolidinopyridine, 1-methyl-4-phenylpyridine, 2-(1-ethylpropyl)pyridine, aminopyridine, and dimethylaminopyridine), pyridazine derivatives, pyrimidine derivatives, pyrazine derivatives, pyrazoline derivatives, pyrazolidine derivatives, piperidine derivatives, piperazine derivatives, morpholine derivatives, indole derivatives, isoindole derivatives, 1H-indazole derivatives, indoline derivatives, quinoline derivatives (e.g., quinoline and 3-quinolinecarbonitrile), isoquinoline derivatives, cinnoline derivatives, quinazoline derivatives, quinoxaline derivatives, phthalazine derivatives, purine derivatives, pteridine derivatives, carbazole derivatives, phenanthridine derivatives, acridine derivatives, phenazine derivatives, 1,10-phenanthroline derivatives, adenine derivatives, adenosine derivatives, guanine derivatives, guanosine derivatives, uracil derivatives, and uridine derivatives.

Examples of suitable carboxyl group-bearing nitrogenous compounds include aminobenzoic acid, indolecarboxylic acid, and amino acid derivatives (e.g. nicotinic acid, alanine, alginine, aspartic acid, glutamic acid, glycine, histidine, isoleucine, glycylleucine, leucine, methionine, phenylalanine, threonine, lysine, 3-aminopyrazine-2-carboxylic acid, and methoxyalanine). Examples of suitable sulfonyl group-bearing nitrogenous compounds include 3-pyridinesulfonic acid and pyridinium p-toluenesulfonate. Examples of suitable hydroxyl group-bearing nitrogenous compounds, hydroxyphenyl group-bearing nitrogenous compounds, and alcoholic nitrogenous compounds include 2-hydroxypyridine, aminocresol, 2,4-quinolinediol, 3-indolemethanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidine ethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyjulolidine, 3-quinuclidinol, 3-tropanol, 1-methyl-2-pyrrolidine ethanol, 1-aziridine ethanol, N-(2-hydroxyethyl)phthalimide, and N-(2-hydroxyethyl)isonicotinamide. Examples of suitable amide derivatives include formamide, N-methylformamide, N,N-dimethylformamide, acetamide, N-methylacetamide, N,N-dimethylacetamide, propionamide, and benzamide. Suitable imide derivatives include phthalimide, succinimide, and maleimide.

In addition, basic compounds of the following general formula (D1) may also be included alone or in admixture.

N(X′)_{w}(Y)_{3-w} (D1)

In the formula, w is equal to 1, 2 or 3; Y is independently hydrogen or a straight, branched or cyclic alkyl group of 1 to 20 carbon atoms which may contain a hydroxyl group or ether structure; and X′ is independently selected from groups of the following general formulas (X′1) to (X′3), and two or three X′ may bond together to form a ring.

—R³⁰⁰—O—R³⁰¹ (X′1)

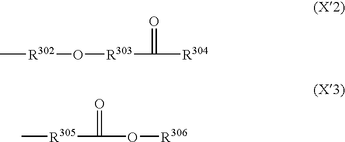

In the formulas, R³⁰⁰, R³⁰² and R³⁰⁵ are independently straight or branched alkylene groups of 1 to 4 carbon atoms; R³⁰¹, R³⁰⁴ and R³⁰⁵ are independently hydrogen, straight, branched or cyclic alkyl groups of 1 to 20 carbon atoms, which may contain at least one hydroxyl group, ether structure, ester structure or lactone ring; and R³⁰³ is a single bond or a straight or branched alkylene group of 1 to 4 carbon atoms.

Illustrative examples of the basic compounds of formula (D1) include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, 4,7,13,16,21,24-hexaoxa-1,10-diazabicyclo[8.8.8]hexacosane, 4,7,13,18-tetraoxa-1,10-diazabicyclo[8.5.5]eicosane, 1,4,10,13-tetraoxa-7,16-diazabicyclooctadecane, 1-aza-12-crown-4,1-aza-15-crown-5,1-aza-18-crown-6, tris(2-formyloxyethyl)amine, tris(2-acetoxyethyl)amine, tris(2-propionyloxyethyl)amine, tris(2-butyryloxyethyl)amine, tris(2-isobutyryloxyethyl)amine, tris(2-valeryloxyethyl)amine, tris(2-pivaloyloxyethyl)amine, N,N-bis(2-acetoxyethyl)-2-(acetoxyacetoxy)ethylamine, tris(2-methoxycarbonyloxyethyl)amine, tris(2-tert-butoxycarbonyloxyethyl)amine, tris[2-(2-oxopropoxy)ethyl]amine, tris[2-(methoxycarbonylmethyl)oxyethyl]amine, tris[2-(tert-butoxycarbonylmethyloxy)ethyl]amine, tris[2-(cyclohexyloxycarbonylmethyloxy)ethyl]amine, tris(2-methoxycarbonylethyl)amine, tris(2-ethoxycarbonylethyl)amine, N,N-bis(2-hydroxyethyl)-2-(methoxycarbonyl)ethylamine, N,N-bis(2-acetoxyethyl)-2-(methoxycarbonyl)ethylamine, N,N-bis(2-hydroxyethyl)-2-(ethoxycarbonyl)ethylamine, N,N-bis(2-acetoxyethyl)-2-(ethoxycarbonyl)ethylamine, N,N-bis(2-hydroxyethyl)-2-(2-methoxyethoxycarbonyl)ethylamine, N,N-bis(2-acetoxyethyl)-2-(2-methoxyethoxycarbonyl)ethylamine, N,N-bis(2-hydroxyethyl)-2-(2-hydroxyethoxycarbonyl)ethylamine, N,N-bis(2-acetoxyethyl)-2-(2-acetoxyethoxycarbonyl)ethylamine, N,N-bis(2-hydroxyethyl)-2-[(methoxycarbonyl)methoxycarbonyl]-ethylamine, N,N-bis(2-acetoxyethyl)-2-[(methoxycarbonyl)methoxycarbonyl]-ethylamine, N,N-bis(2-hydroxyethyl)-2-(2-oxopropoxycarbonyl)ethylamine, N,N-bis(2-acetoxyethyl)-2-(2-oxopropoxycarbonyl)ethylamine, N,N-bis(2-hydroxyethyl)-2-(tetrahydrofurfuryloxycarbonyl)ethylamine, N,N-bis(2-acetoxyethyl)-2-(tetrahydrofurfuryloxycarbonyl)ethylamine, N,N-bis(2-hydroxyethyl)-2-[(2-oxotetrahydrofuran-3-yl)oxycarbonyl]ethylamine, N,N-bis(2-acetoxyethyl)-2-[(2-oxotetrahydrofuran-3-yl)oxycarbonyl]ethylamine, N,N-bis(2-hydroxyethyl)-2-(4-hydroxybutoxycarbonyl)ethylamine, N,N-bis(2-formyloxyethyl)-2-(4-formyloxybutoxycarbonyl)ethylamine, N,N-bis(2-formyloxyethyl)-2-(2-formyloxyethoxycarbonyl)ethylamine, N,N-bis(2-methoxyethyl)-2-(methoxycarbonyl)ethylamine, N-(2-hydroxyethyl)-bis[2-(methoxycarbonyl)ethyl]amine, N-(2-acetoxyethyl)-bis[2-(methoxycarbonyl)ethyl]amine, N-(2-hydroxyethyl)-bis[2-(ethoxycarbonyl)ethyl]amine, N-(2-acetoxyethyl)-bis[2-(ethoxycarbonyl)ethyl]amine, N-(3-hydroxy-1-propyl)-bis[2-(methoxycarbonyl)ethyl]amine, N-(3-acetoxy-1-propyl)-bis[2-(methoxycarbonyl)ethyl]amine, N-(2-methoxyethyl)-bis[2-(methoxycarbonyl)ethyl]amine, N-butyl-bis[2-(methoxycarbonyl)ethyl]amine, N-butyl-bis[2-(2-methoxyethoxycarbonyl)ethyl]amine, N-methyl-bis(2-acetoxyethyl)amine, N-ethyl-bis(2-acetoxyethyl)amine, N-methyl-bis(2-pivaloyloxyethyl)amine, N-ethyl-bis[2-(methoxycarbonyloxy)ethyl]amine, N-ethyl-bis[2-(tert-butoxycarbonyloxy)ethyl]amine, tris(methoxycarbonylmethyl)amine, tris(ethoxycarbonylmethyl)amine, N-butyl-bis(methoxycarbonylmethyl)amine, N-hexyl-bis(methoxycarbonylmethyl)amine, and β-(diethylamino)-δ-valerolactone.

Also useful are one or more of cyclic structure-bearing basic compounds having the following general formula (D2).

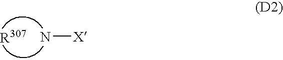

Herein X′ is as defined above, and R³⁰⁷ is a straight or branched alkylene group of 2 to 20 carbon atoms which may contain one or more carbonyl groups, ether structures, ester structures or sulfide structures.

Illustrative examples of the cyclic structure-bearing basic compounds having formula (D2) include 1-[2-(methoxymethoxy)ethyl]pyrrolidine, 1-[2-(methoxymethoxy)ethyl]piperidine, 4-[2-(methoxymethoxy)ethyl]morpholine, 1-[2-[(2-methoxyethoxy)methoxy]ethyl]pyrrolidine, 1-[2-[(2-methoxyethoxy)methoxy]ethyl]piperidine, 4-[2-[(2-methoxyethoxy)methoxy]ethyl]morpholine, 2-(1-pyrrolidinyl)ethyl acetate, 2-piperidinoethyl acetate, 2-morpholinoethyl acetate, 2-(1-pyrrolidinyl)ethyl formate, 2-piperidinoethyl propionate, 2-morpholinoethyl acetoxyacetate, 2-(1-pyrrolidinyl)ethyl methoxyacetate, 4-[2-(methoxycarbonyloxy)ethyl]morpholine, 1-[2-(t-butoxycarbonyloxy)ethyl]piperidine, 4-[2-(2-methoxyethoxycarbonyloxy)ethyl]morpholine, methyl 3-(1-pyrrolidinyl)propionate, methyl 3-piperidinopropionate, methyl 3-morpholinopropionate, methyl 3-(thiomorpholino)propionate, methyl 2-methyl-3-(1-pyrrolidinyl)propionate, ethyl 3-morpholinopropionate, methoxycarbonylmethyl 3-piperidinopropionate, 2-hydroxyethyl 3-(1-pyrrolidinyl)propionate, 2-acetoxyethyl 3-morpholinopropionate, 2-oxotetrahydrofuran-3-yl 3-(1-pyrrolidinyl)propionate, tetrahydrofurfuryl 3-morpholinopropionate, glycidyl 3-piperidinopropionate, 2-methoxyethyl 3-morpholinopropionate, 2-(2-methoxyethoxy)ethyl 3-(1-pyrrolidinyl)propionate, butyl 3-morpholinopropionate, cyclohexyl 3-piperidinopropionate, α-(1-pyrrolidinyl)methyl-γ-butyrolactone, β-piperidino-γ-butyrolactone, β-morpholino-δ-valerolactone, methyl 1-pyrrolidinylacetate, methyl piperidinoacetate, methyl morpholinoacetate, methyl thiomorpholinoacetate, ethyl 1-pyrrolidinylacetate, and 2-methoxyethyl morpholinoacetate.

Also, one or more of cyano-bearing basic compounds having the following general formulae (D3) to (D6) may be blended.

(X′)_{3-w}—N—(R³⁰⁸—CN)_{w} (D3)

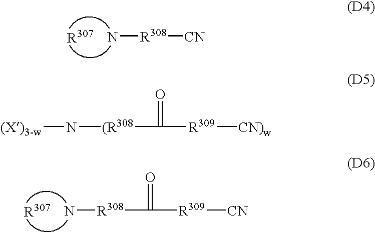

Herein, X′, R³⁰⁷ and w are as defined above, and R³⁰⁸ and R³⁰⁹ each are independently a straight or branched alkylene group of 1 to 4 carbon atoms.

Illustrative examples of the cyano-bearing basic compounds having formulae (D3) to (D6) include 3-(diethylamino)propiononitrile, N,N-bis(2-hydroxyethyl)-3-aminopropiononitrile, N,N-bis(2-acetoxyethyl)-3-aminopropiononitrile, N,N-bis(2-formyloxyethyl)-3-aminopropiononitrile, N,N-bis(2-methoxyethyl)-3-aminopropiononitrile, N,N-bis[2-(methoxymethoxy)ethyl]-3-aminopropiononitrile, methyl N-(2-cyanoethyl)-N-(2-methoxyethyl)-3-aminopropionate, methyl N-(2-cyanoethyl)-N-(2-hydroxyethyl)-3-aminopropionate, methyl N-(2-acetoxyethyl)-N-(2-cyanoethyl)-3-aminopropionate, N-(2-cyanoethyl)-N-ethyl-3-aminopropiononitrile, N-(2-cyanoethyl)-N-(2-hydroxyethyl)-3-aminopropiononitrile, N-(2-acetoxyethyl)-N-(2-cyanoethyl)-3-aminopropiononitrile, N-(2-cyanoethyl)-N-(2-formyloxyethyl)-3-aminopropiononitrile, N-(2-cyanoethyl)-N-(2-methoxyethyl)-3-aminopropiononitrile, N-(2-cyanoethyl)-N-[2-(methoxymethoxy)ethyl]-3-aminopropiononitrile, N-(2-cyanoethyl)-N-(3-hydroxy-1-propyl)-3-aminopropiononitrile, N-(3-acetoxy-1-propyl)-N-(2-cyanoethyl)-3-aminopropiononitrile, N-(2-cyanoethyl)-N-(3-formyloxy-1-propyl)-3-aminopropiononitrile, N-(2-cyanoethyl)-N-tetrahydrofurfuryl-3-aminopropiononitrile, N,N-bis(2-cyanoethyl)-3-aminopropiononitrile, diethylaminoacetonitrile, N,N-bis(2-hydroxyethyl)aminoacetonitrile, N,N-bis(2-acetoxyethyl)aminoacetonitrile, N,N-bis (2-formyloxyethyl)aminoacetonitrile, N,N-bis(2-methoxyethyl)aminoacetonitrile, N,N-bis[2-(methoxymethoxy)ethyl]aminoacetonitrile, methyl N-cyanomethyl-N-(2-methoxyethyl)-3-aminopropionate, methyl N-cyanomethyl-N-(2-hydroxyethyl)-3-aminopropionate, methyl N-(2-acetoxyethyl)-N-cyanomethyl-3-aminopropionate, N-cyanomethyl-N-(2-hydroxyethyl)aminoacetonitrile, N-(2-acetoxyethyl)-N-(cyanomethyl)aminoacetonitrile, N-cyanomethyl-N-(2-formyloxyethyl)aminoacetonitrile, N-cyanomethyl-N-(2-methoxyethyl)aminoacetonitrile, N-cyanomethyl-N-[2-(methoxymethoxy)ethyl]aminoacetonitrile, N-cyanomethyl-N-(3-hydroxy-1-propyl)aminoacetonitrile, N-(3-acetoxy-1-propyl)-N-(cyanomethyl)aminoacetonitrile, N-cyanomethyl-N-(3-formyloxy-1-propyl)aminoacetonitrile, N,N-bis (cyanomethyl)aminoacetonitrile, 1-pyrrolidinepropiononitrile, 1-piperidinepropiononitrile, 4-morpholinepropiononitrile, 1-pyrrolidineacetonitrile, 1-piperidineacetonitrile, 4-morpholineacetonitrile, cyanomethyl 3-diethylaminopropionate, cyanomethyl N,N-bis(2-hydroxyethyl)-3-aminopropionate, cyanomethyl N,N-bis(2-acetoxyethyl)-3-aminopropionate, cyanomethyl N,N-bis(2-formyloxyethyl)-3-aminopropionate, cyanomethyl N,N-bis(2-methoxyethyl)-3-aminopropionate, cyanomethyl N,N-bis[2-(methoxymethoxy)ethyl]-3-aminopropionate, 2-cyanoethyl 3-diethylaminopropionate, 2-cyanoethyl N,N-bis(2-hydroxyethyl)-3-aminopropionate, 2-cyanoethyl N,N-bis(2-acetoxyethyl)-3-aminopropionate, 2-cyanoethyl N,N-bis(2-formyloxyethyl)-3-aminopropionate, 2-cyanoethyl N,N-bis(2-methoxyethyl)-3-aminopropionate, 2-cyanoethyl N,N-bis[2-(methoxymethoxy)ethyl]-3-aminopropionate, cyanomethyl 1-pyrrolidinepropionate, cyanomethyl 1-piperidinepropionate, cyanomethyl 4-morpholinepropionate, 2-cyanoethyl 1-pyrrolidinepropionate, 2-cyanoethyl 1-piperidinepropionate, and 2-cyanoethyl 4-morpholinepropionate.

The basic compounds may be used alone or in admixture of two or more. The basic compound is preferably formulated in an amount of 0 to 2 parts, and especially 0.01 to 1 part by weight, per 100 parts by weight of the solids in the resist composition. The use of more than 2 parts of the basis compound would result in too low a sensitivity.

Component (E)

Illustrative, non-limiting, examples of the organic acid derivatives (E) include phenol, cresol, catechol, resorcinol, pyrogallol, fluoroglycin, bis(4-hydroxyphenyl)methane, 2,2-bis(4′-hydroxyphenyl)propane, bis(4-hydroxyphenyl)sulfone, 1,1,1-tris(4′-hydroxyphenyl)ethane, 1,1,2-tris(4′-hydroxyphenyl)ethane, hydroxybenzophenone, 4-hydroxyphenylacetic acid, 3-hydroxyphenylacetic acid, 2-hydroxyphenylacetic acid, 3-(4-hydroxyphenyl)propionic acid, 3-(2-hydroxyphenyl)propionic acid, 2,5-dihydroxyphenylacetic acid, 3,4-dihydroxyphenylacetic acid, 1,2-phenylenediacetic acid, 1,3-phenylenediacetic acid, 1,4-phenylenediacetic acid, 1,2-phenylenedioxydiacetic acid, 1,4-phenylenedipropanoic acid, benzoic acid, salicylic acid, 4,4-bis(4′-hydroxyphenyl)valeric acid, 4-tert-butoxyphenylacetic acid, 4-(4-hydroxyphenyl)butyric acid, 3,4-dihydroxymandelic acid, and 4-hydroxymandelic acid. Of these, salicylic acid and 4,4-bis(4′-hydroxyphenyl)valeric acid are preferred. They may be used alone or in admixture of two or more.

In the resist composition of the invention, the organic acid derivative is preferably formulated in an amount of up to 5 parts, and especially up to 1 part by weight, per 100 parts by weight of the solids in the resist composition. The use of more than 5 parts of the organic acid derivative would result in too low a resolution. Depending on the combination of the other components in the resist composition, the organic acid derivative may be omitted.

Component (F)

Component (F) is an organic solvent. Illustrative, non-limiting, examples include butyl acetate, amyl acetate, cyclohexyl acetate, 3-methoxybutyl acetate, methyl ethyl ketone, methyl amyl ketone, cyclohexanone, cyclopentanone, 3-ethoxyethyl propionate, 3-ethoxymethyl propionate, 3-methoxymethyl propionate, methyl acetoacetate, ethyl acetoacetate, diacetone alcohol, methylpyruvate, ethyl pyruvate, propylene glycol monomethyl ether, propylene glycol monoethyl ether, propylene glycol monomethyl ether propionate, propylene glycol monoethyl ether propionate, ethylene glycol monomethyl ether, ethylene glycol monoethyl ether, diethylene glycol monomethyl ether, diethylene glycol monoethyl ether, 3-methyl-3-methoxybutanol, N-methylpyrrolidone, dimethyl sulfoxide, γ-butyrolactone, propylene glycol methyl ether acetate, propylene glycol ethyl ether acetate, propylene glycol propyl ether acetate, methyl lactate, ethyl lactate, propyl lactate, and tetramethyl sulfone. Of these, the propylene glycol alkyl ether acetates and alkyl lactates are especially preferred. The solvents may be used alone or in admixture of two or more. An exemplary useful solvent mixture is a mixture of a propylene glycol alkyl ether acetate and an alkyl lactate. It is noted that the alkyl groups of the propylene glycol alkyl ether acetates are preferably those of 1 to 4 carbon atoms, for example, methyl, ethyl and propyl, with methyl and ethyl being especially preferred. Since the propylene glycol alkyl ether acetates include 1,2- and 1,3-substituted ones, each includes three isomers depending on the combination of substituted positions, which may be used alone or in admixture. It is also noted that the alkyl groups of the alkyl lactates are preferably those of 1 to 4 carbon atoms, for example, methyl, ethyl and propyl, with methyl and ethyl being especially preferred.

When the propylene glycol alkyl ether acetate is used as the solvent, it preferably accounts for at least 50% by weight of the entire solvent. Also when the alkyl lactate is used as the solvent, it preferably accounts for at least 50% by weight of the entire solvent. When a mixture of propylene glycol alkyl ether acetate and alkyl lactate is used as the solvent, that mixture preferably accounts for at least 50% by weight of the entire solvent. It is more preferred to mix 60 to 95% by weight of the propylene glycol alkyl ether acetate with 40 to 5% by weight of the alkyl lactate. A lower proportion of the propylene glycol alkyl ether acetate would invite a problem of inefficient coating whereas a higher proportion thereof would provide insufficient dissolution and allow for particle and foreign matter formation. A lower proportion of the alkyl lactate would provide insufficient dissolution and cause the problem of many particles and foreign matter whereas a higher proportion thereof would lead to a composition which has a too high viscosity to apply and loses storage stability.

The solvent is preferably used in an amount of 300 to 2,000 parts by weight, especially 400 to 1,000 parts by weight per 100 parts by weight of the solids in the resist composition. The solvent concentration is not limited thereto as long as a film can be formed by existing methods.

Component (G)

In one preferred embodiment, the resist composition further contains (G) a compound with a molecular weight of up to 3,000 which changes its solubility in an alkaline developer under the action of an acid, that is, a dissolution inhibitor. Typically, a compound obtained by partially or entirely substituting acid labile substituents on a phenol or carboxylic acid derivative having a molecular weight of up to 2,500 is added as the dissolution inhibitor.

Examples of the phenol or carboxylic acid derivative having a molecular weight of up to 2,500 include bisphenol A, bisphenol H, bisphenol S, 4,4-bis(4′-hydroxyphenyl)valeric acid, tris(4-hydroxyphenyl)methane, 1,1,1-tris(4′-hydroxyphenyl)ethane, 1,1,2-tris(4′-hydroxyphenyl)ethane, phenolphthalein, and thymolphthalein. The acid labile substituents are the same as those exemplified as the acid labile groups in the polymer.

Illustrative, non-limiting, examples of the dissolution inhibitors which are useful herein include bis(4-(2′-tetrahydropyranyloxy)phenyl)methane, bis(4-(2′-tetrahydrofuranyloxy)phenyl)methane, bis(4-tert-butoxyphenyl)methane, bis(4-tert-butoxycarbonyloxyphenyl)methane, bis(4-tert-butoxycarbonylmethyloxyphenyl)methane, bis(4-(1′-ethoxyethoxy)phenyl)methane, bis(4-(1′-ethoxypropyloxy)phenyl)methane, 2,2-bis(4′-(2″-tetrahydropyranyloxy))propane, 2,2-bis(4′-(2″-tetrahydrofuranyloxy)phenyl)propane, 2,2-bis(4′-tert-butoxyphenyl)propane, 2,2-bis(4′-tert-butoxycarbonyloxyphenyl)propane, 2,2-bis(4-tert-butoxycarbonylmethyloxyphenyl)propane, 2,2-bis(4′-(1″-ethoxyethoxy)phenyl)propane, 2,2-bis(4′-(1″-ethoxypropyloxy)phenyl)propane, tert-butyl 4,4-bis(4′-(2″-tetrahydropyranyloxy)phenyl)valerate, tert-butyl 4,4-bis(4′-(2″-tetrahydrofuranyloxy)phenyl)valerate, tert-butyl 4,4-bis(4′-tert-butoxyphenyl)valerate, tert-butyl 4,4-bis(4-tert-butoxycarbonyloxyphenyl)valerate, tert-butyl 4,4-bis(4′-tert-butoxycarbonylmethyloxyphenyl)valerate, tert-butyl 4,4-bis(4′-(1″-ethoxyethoxy)phenyl)valerate, tert-butyl 4,4-bis(4′-(1″-ethoxypropyloxy)phenyl)valerate, tris(4-(2′-tetrahydropyranyloxy)phenyl)methane, tris(4-(2′-tetrahydrofuranyloxy)phenyl)methane, tris(4-tert-butoxyphenyl)methane, tris(4-tert-butoxycarbonyloxyphenyl)methane, tris(4-tert-butoxycarbonyloxymethylphenyl)methane, tris(4-(1′-ethoxyethoxy)phenyl)methane, tris(4-(1′-ethoxypropyloxy)phenyl)methane, 1,1,2-tris(4′-(2″-tetrahydropyranyloxy)phenyl)ethane, 1,1,2-tris(4′-(2″-tetrahydrofuranyloxy)phenyl)ethane, 1,1,2-tris(4′-tert-butoxyphenyl)ethane, 1,1,2-tris(4′-tert-butoxycarbonyloxyphenyl)ethane, 1,1,2-tris(4′-tert-butoxycarbonylmethyloxyphenyl)ethane, 1,1,2-tris(4′-(1′-ethoxyethoxy)phenyl)ethane, and 1,1,2-tris(4′-(1′-ethoxypropyloxy)phenyl)ethane.

In the resist composition of the invention, an appropriate amount of the dissolution inhibitor is up to 20 parts, and especially up to 15 parts by weight per 100 parts by weight of the solids in the resist composition. With more than 20 parts of the dissolution inhibitor, the resist composition becomes less heat resistant because of an increased content of monomer components.

In the chemical amplification type resist composition according to the invention, there may be added such additives as a surfactant for improving coating, and a light absorbing agent for reducing diffuse reflection from the substrate.

Illustrative, non-limiting, examples of the surfactant include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene polyoxypropylene block copolymers, sorbitan fatty acid esters such as sorbitan monolaurate, sorbitan monopalmitate, and sorbitan monostearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants such as EFTOP EF301, EF303 and EF352 (Tohkem Products Co., Ltd.), Megaface F171, F172 and F173 (Dai-Nippon Ink & Chemicals, Inc.), Florade FC430 and FC431 (Sumitomo 3M Co., Ltd.), Aashiguard AG710, Surflon S-381, S-382, SC101, SC102, SC103, SC104, SC105, SC106, Surfynol E1004, KH-10, KH-20, KH-30 and KH-40 (Asahi Glass Co., Ltd.); organosiloxane polymers KP341, X-70-092 and X-70-093 (Shin-Etsu Chemical Co., Ltd.), acrylic acid or methacrylic acid Polyflow No. 75 and No. 95 (Kyoeisha Ushi Kagaku Kogyo Co., Ltd.). Inter alia, FC430, Surflon S-381, Surfynol E1004, KH-20 and KH-30 are preferred. These surfactants may be used alone or in admixture.

In the chemically amplified resist composition according to the invention, the surfactant is preferably formulated in an amount of up to 2 parts, and especially up to 1 part by weight, per 100 parts by weight of the solids in the resist composition.

In the chemically amplified resist composition according to the invention, a UV absorber may be added. Those UV absorbers described in JP-A 11-190904 are useful, but the invention is not limited thereto. Exemplary UV absorbers are diaryl sulfoxide derivatives such as bis(4-hydroxyphenyl) sulfoxide, bis(4-tert-butoxyphenyl) sulfoxide, bis(4-tert-butoxycarbonyloxyphenyl) sulfoxide, and bis[4-(1-ethoxyethoxy)phenyl] sulfoxide; diarylsulfone derivatives such as bis(4-hydroxyphenyl)sulfone, bis(4-tert-butoxyphenyl)sulfone, bis(4-tert-butoxycarbonyloxyphenyl)sulfone, bis[4-(1-ethoxyethoxy)phenyl]sulfone, and bis[4-(1-ethoxypropoxy)phenyl]sulfone; diazo compounds such as benzoquinonediazide, naphthoquinonediazide, anthraquinonediazide, diazofluorene, diazotetralone, and diazophenanthrone; quinonediazide group-containing compounds such as complete or partial ester compounds between naphthoquinone-1,2-diazide-5-sulfonic acid chloride and 2,3,4-trihydroxybenzophenone and complete or partial ester compounds between naphthoquinone-1,2-diazide-4-sulfonic acid chloride and 2,4,4′-trihydroxybenzophenone; tert-butyl 9-anthracenecarboxylate, tert-amyl 9-anthracenecarboxylate, tert-methoxymethyl 9-anthracenecarboxylate, tert-ethoxyethyl 9-anthracenecarboxylate, 2-tert-tetrahydropyranyl 9-anthracenecarboxylate, and 2-tert-tetrahydrofuranyl 9-anthracenecarboxylate. The UV absorber may or may not be added to the resist composition depending on the type of resist composition. An appropriate amount of UV absorber, if added, is 0 to 10 parts, more preferably 0.5 to 10 parts, most preferably 1 to 5 parts by weight per 100 parts by weight of the base resin.

For the microfabrication of integrated circuits, any well-known lithography may be used to form a resist pattern from the chemically amplified positive resist composition comprising the photoacid generator of formula (1), (1a) or (1b) according to the invention.

The composition is applied onto a substrate (e.g., Si, SiO₂, SiN, SiON, TiN, WSi, BPSG, SOG, organic anti-reflecting film, etc.) for microfabrication by a suitable coating technique such as spin coating, roll coating, flow coating, dip coating, spray coating or doctor coating. The coating is prebaked on a hot plate at a temperature of 60 to 150° C. for about 1 to 10 minutes, preferably 80 to 120° C. for 1 to 5 minutes. The resulting resist film is generally 0.1 to 2.0 μm thick. Through a photomask having a desired pattern, the resist film is then exposed to radiation, preferably having an exposure wavelength of up to 300 nm, such as UV, deep-UV, electron beams, x-rays, excimer laser light, γ-rays and synchrotron radiation. The preferred light source is a beam from an excimer laser, especially KrF excimer laser or deep UV of 245-255 nm wavelength. The exposure dose is preferably in the range of about 1 to 200 mJ/cm², more preferably about 10 to 100 mJ/cm². The film is further baked on a hot plate at 60 to 150° C. for 1 to 5 minutes, preferably 80 to 120° C. for 1 to 3 minutes (post-exposure baking=PEB).

Thereafter the resist film is developed with a developer in the form of an aqueous base solution, for example, 0.1 to 5%, preferably 2 to 3% aqueous solution of tetramethylammonium hydroxide (TMAH) for 0.1 to 3 minutes, preferably 0.5 to 2 minutes by conventional techniques such as dipping, puddling or spraying. In this way, a desired resist pattern is formed on the substrate. It is appreciated that the resist composition of the invention is best suited for micro-patterning using such actinic radiation as deep UV with a wavelength of 254 to 193 nm, vacuum UV with a wavelength of 157 nm, electron beams, x-rays, excimer laser light, γ-rays and synchrotron radiation. With any of the above-described parameters outside the above-described range, the process may sometimes fail to produce the desired pattern.

### EXAMPLE

Examples of the invention are given below by way of illustration and not by way of limitation.

### Synthesis Example 1

Synthesis of (5-hydroxyimino-5H-thiophen-2-ylidene)-(2-methylphenyl)-acetonitrile

Reaction was carried out in accordance with the procedure of JP-A 2002-508774 using o-xylyl cyanide and 2-nitrothiophene as reactants in methanol in the presence of potassium hydroxide as a base, thereby synthesizing the end compound (yellow crystals, yield 34%).

### Synthesis Example 2

Synthesis of (5-(2,4,6-triisopropylbenzenesulfonyloxy)imino-5H-thiophen-2-ylidene)-(2-methylphenyl)-acetonitrile

In 350 g of tetrahydrofuran were dissolved 40.1 g (0.166 mol) of (5-hydroxyimino-5H-thiophen-2-ylidene)-(2-methylphenyl)-acetonitrile obtained in Synthesis Example 1 and 50.0 g (0.166 mol) of commercially available 2,4,6-triisopropylbenzenesulfonyl chloride. Then 17.6 g (0.174 mol) of triethylamine was added. After one hour of stirring at room temperature, 150 g of water was added and the organic layer separated was taken out. The organic layer was combined with 500 g of dichloromethane and washed with water. Using a rotary evaporator, the solvent was distilled off in vacuum. To 100 g of the residue, 300 g of methanol was added for re-crystallization. The crystals were filtered in vacuum and washed with a small amount of methanol. Vacuum drying yielded 69.5 g of the end compound (yellow crystals, yield 82%).

The compound thus obtained was analyzed by nuclear magnetic resonance (NMR) spectroscopy and infrared (1R) absorption spectroscopy, with the results shown below. Although the compound obtained could be either of or a mixture of two isomers of the structure shown below, it was judged from the spectra that the product was either one single compound.

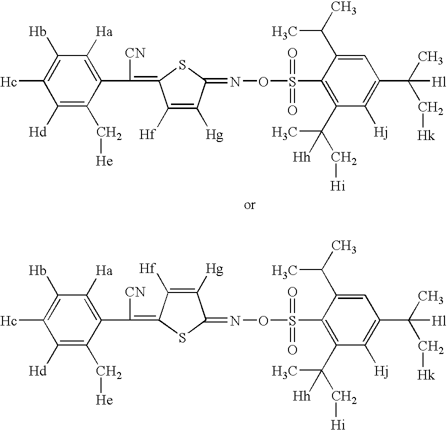

¹H-NMR: CDCl₃ (ppm)

1.25-1.27 (6H, d, Hk)

1.28-1.30 (12H, d, Hi)

2.30 (3H, s, He)

2.85-2.99 (1H, m, Hl)

4.16-4.30 (2H, m, Hh)

6.08-6.10 (1H, d, Hg or Hf)

6.78-6.80 (1H, d, Hf or Hg)

7.12-7.15 (1H, d, Hd)

7.18-7.34 (3H, m, Hc, Hd, He)

IR: cm⁻¹

2958, 2927, 2870, 1597, 1461, 1425, 1383, 1356, 1327, 1184, 1159, 1103, 883, 852, 783, 768, 731, 704, 687, 663, 650, 602

### Synthesis Example 3

Synthesis of (4-(2,4,6-triisopropylbenzenesulfonyloxy)imino-cyclohexa-2,5-dienylidene)phenylacetonitrile

An oxime was synthesized in accordance with the procedure of JP-A 2002-508774 using phenylacetonitrile and nitrobenzene as reactants. Thereafter, as in Synthesis Example 2, it was reacted with 2,4,6-triisopropylbenzenesulfonyl chloride under basic conditions, thereby synthesizing the end compound.

### Synthesis Example 4

Synthesis of geometric isomer of Synthesis Example 2

A mixture of 20 g of (5-(2,4,6-triisopropylbenzenesulfonyloxy)imino-5H-thiophen-2-ylidene)-(2-methylphenyl)acetonitrile obtained in Synthesis Example 2, 192 g of methanol, 72 g of 1,2-dichloroethane and 18 g of conc. sulfuric acid was heated on an oil bath at 80° C. for 48 hours. To the reaction solution, 400 g of water and 500 g of dichloromethane were added. The organic layer was separated and washed with 300 g of water. Using a rotary evaporator, the solvent was distilled off in vacuum. To 40 g of the residue, 40 g of methanol was added for crystallization. The crystals were filtered off, and the filtrate was concentrated and worked up by silica gel column chromatography (eluent: a mixture of hexane and ethyl acetate) and re-crystallization. There was obtained 0.3 g of the end geometric isomer (yellow crystals, yield 1.5%). The geometric isomer thus obtained was analyzed by NMR and IR spectroscopy, with the results shown below. The Synthesis Example 2 compound and the geometric isomer were also analyzed by high performance liquid chromatography (HPLC), with the results shown below.

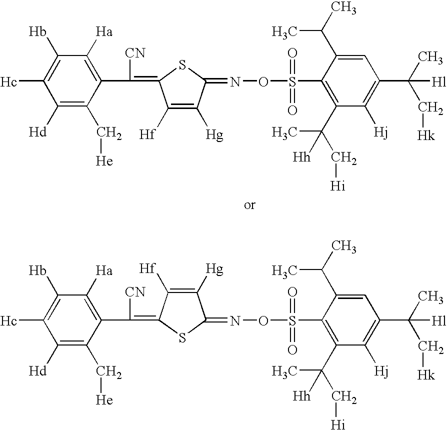

¹H-NMR: CDCl₃ (ppm)

1.126-1.149 (12H, d, Hi)

1.288-1.311 (6H, d, Hk)

2.091 (3H, s, He)

2.869-3.007 (1H, m, Hl)

3.480-3.839 (2H, m, Hh)

6.846-6.868 (1H, d, Hg or Hf)

6.950-6.972 (1H, d, Hf or Hg)

6.881-7.116 (4H, m, Ha, Hb, Hc, Hd)

IR: cm⁻¹

3080, 2960, 2927, 2872, 2204, 1597, 1560, 1547, 1524, 1462, 1423, 1387, 1362, 1354, 1321, 1184, 1157, 1105, 1093, 1039, 883, 864, 854, 785, 773, 756, 742, 723, 700, 687, 661, 623, 611, 553, 526

HPLC Analysis Conditions:

Instrument: liquid chromatograph L-7000 by Hitachi Ltd.

Column: L-column ODS (40° C.) by the Chemicals Evaluation and Research Institute, Japan

Mobile phase: acetonitrile/water=95/5 (volume ratio), 1 ml/min

Detector: DAD detector L-7455 (410 nm) by Hitachi Ltd.

Test liquid: 0.1 wt % mobile phase solution, 25 μL

Results of HPLC Analysis

Holding time and purity of geometric isomer:

6.04 min, 97.97% pure

Holding time and purity of Synthesis Example 2 compound:

5.79 min, 98.5% pure

When a mixture of equal amounts of Synthesis Example 2 compound and the geometric isomer was analyzed by HPLC, two separate peaks appeared rather than a common peak.

It is evident from these results that Synthesis Example 2 compound is distinct from the geometric isomer.

### Examples 1-22 and Comparative Examples 1-3

Resist materials were prepared in accordance with the formulation shown in Tables 1 to 3. The components used are shown below.

Polymer A: poly(p-hydroxystyrene) in which hydroxyl groups are protected with 15 molt of 1-ethoxyethyl groups and 15 molt of tert-butoxycarbonyl groups, having a weight average molecular weight of 12,000.

Polymer B: poly(p-hydroxystyrene) in which hydroxyl groups are protected with 30 molt of 1-ethoxyethyl groups, having a weight average molecular weight of 12,000.

Polymer C: poly(p-hydroxystyrene) in which hydroxyl groups are protected with 25 molt of 1-ethoxyethyl groups and crosslinked with 3 molt of 1,2-propanediol divinyl ether, having a weight average molecular weight of 13,000.

Polymer D: poly(p-hydroxystyrene) in which hydroxyl groups are protected with 25 molt of tert-butoxycarbonyl groups, having a weight average molecular weight of 12,000.

Polymer E: p-hydroxystyrene/2-ethyl-2-adamantyl methacrylate copolymer having a compositional ratio (molar ratio) of 70:30 and a weight average molecular weight of 9,000.

Polymer F: p-hydroxystyrene/1-ethyl-1-norbornene methacrylate copolymer having a compositional ratio (molar ratio) of 70:30 and a weight average molecular weight of 15,000.

Polymer G: p-hydroxystyrene/tert-butyl acrylate copolymer having a compositional ratio (molar ratio) of 65:35 and a weight average molecular weight of 15,000.

Polymer H: p-hydroxystyrene/1-ethylcyclopentyl methacrylate copolymer having a compositional ratio (molar ratio) of 65:35 and a weight average molecular weight of 15,000.

Polymer I: p-hydroxystyrene/1-ethylcyclopentyl methacrylate/indene copolymer having a compositional ratio (molar ratio) of 74:13:13 and a weight average molecular weight of 12,000.

Polymer J: p-hydroxystyrene/2-ethyl-2-adamantyl methacrylate/indene copolymer having a compositional ratio (molar ratio) of 80:10:10 and a weight average molecular weight of 10,000.

Polymer K: p-hydroxystyrene/styrene/1-ethyl-1-norbornene methacrylate copolymer having a compositional ratio (molar ratio) of 70:10:20 and a weight average molecular weight of 10,000.

PAG1: compound of Synthesis Example 2

PAG2: compound of Synthesis Example 3

PAG3: triphenylsulfonium 2,4,6-triisopropylbenzenesulfonate

PAG4: (4-tert-butoxyphenyl)diphenylsulfonium 10-camphorsulfonate

PAG5: bis(cyclohexylsulfonyl)diazomethane

PAG6: bis(2,4-dimethylphenylsulfonyl)diazomethane

PAG7: (5-(10-camphorsulfonyloxy)imino-5H-thiophen-2-ylidene)-(2-methylphenyl)-acetonitrile

Dissolution inhibitor: bis(4-(21-tetrahydropyranyloxy)phenyl)methane

Basic compound A: triethanol amine

Basic compound B: tris(2-methoxyethyl)amine

Organic acid derivative A: 4,4-bis(4′-hydroxyphenyl)valeric acid

Organic acid derivative B: salicylic acid

Surfactant A: FC-430 (Sumitomo 3M Co., Ltd.)

Surfactant B: Surflon S-381 (Asahi Glass Co., Ltd.)

Solvent A: propylene glycol methyl ether acetate

Solvent B: ethyl lactate

The resist materials thus obtained were each filtered through a 0.2-μm Teflon® filter, thereby giving resist solutions. These resist solutions were spin-coated onto silicon wafers having an organic antireflection film (DUV-44, Brewer Science) of 800 Å thick coated thereon, so as to give a dry thickness of 0.6 μm.

The coated silicon wafer was then baked on a hot plate at 100° C. for 90 seconds. The resist films were exposed to ⅔ annular illumination using an excimer laser stepper NSR-S202A (Nikon Corp., NA 0.6), then baked (PEB) at 110° C. for 90 seconds, and developed with a solution of 2.38% tetramethylammonium hydroxide (TMAH) in water, thereby giving positive patterns.

The resulting resist patterns were evaluated as described below.

Resist Pattern Evaluation

The optimum exposure dose (sensitivity Eop) was the exposure dose which provided a 1:1 resolution at the top and bottom of a 0.18-μm line-and-space pattern. The minimum line width (μm) of a line-and-space pattern which was ascertained separate at this dose was the resolution of a test resist. The shape in cross section of the resolved resist pattern was examined under a scanning electron microscope. The depth of focus (DOF) was determined by offsetting the focal point and judging the resist to be satisfactory when the resist pattern shape was kept rectangular and the resist pattern film thickness was kept above 80% of that at accurate focusing.

The PED stability of a resist was evaluated by effecting post-exposure bake (PED) after 24 hours of holding from exposure at the optimum dose and determining a variation in line width. The less the variation, the greater is the PED stability.

The results of resist pattern evaluation are shown in Table 4.

Other Evaluation

The solubility of resist material in a solvent mixture was examined by visual observation and in terms of clogging upon filtration.

With respect to the applicability of a resist solution, uneven coating was visually observed. Additionally, using a film gage Clean Lambda Ace VM-3010 (optical interference film gage by Dainippon Screen Mfg. Co., Ltd.), the thickness of a resist film on a common wafer was measured at different positions, based on which a variation from the desired coating thickness (0.6 μm) was calculated. The applicability was rated “good” when the variation was within 0.5% (that is, within 0.003 μm), “unacceptable” when the variation was from more than 0.5% to 1%, and “poor” when the variation was more than 1%.

Storage stability was judged in terms of foreign matter precipitation or sensitivity change with the passage of time. After the resist solution was aged for 100 days at the longest, the number of particles of 0.3 μm or larger per ml of the resist solution was counted by means of a particle counter KL-20A (Rion Co., Ltd.). Also, a change with time of sensitivity (Eop) from that immediately after preparation was determined. The storage stability was rated “good” when the number of particles is not more than 5 or when the sensitivity change was within 5%, and “poor” otherwise.

Debris appearing on the developed pattern was observed under a scanning electron microscope (TDSEM) model S-9200 (Hitachi Ltd.). The resist film was rated “good” when the number of foreign particles within 100 μm square is 3 or less, “unacceptable” when the number is from 4 to 9, and “poor” when the number is 10 or more.

Debris left after resist peeling was examined using a surface scanner Surf-Scan 6220 (Tencol Instruments). A resist-coated 8-inch wafer was subjected to entire exposure rather than patterned exposure, processed in a conventional manner, and developed with a 2.38% TMAH solution before the resist film was peeled off (only the resist film in the exposed area was peeled). After the resist film was peeled, the wafer was examined and rated “good” when the number of foreign particles of greater than 0.20 μm was up to 100, “unacceptable” when from 101 to 150, and “poor” when more than 150.

The results are shown in Table 5.

TABLE 1

| Composition | Example | | | | | | | | | | | |
|---|---|---|---|---|---|---|---|---|---|---|---|---|
| (pbw) | 1 | 2 | 3 | 4 | 5 | 6 | 7 | 8 | 9 | 10 | 11 | 12 |
| Polymer A | 80 | | | | | | | | | | | |
| Polymer B | | 80 | | | | | | | | | | 40 |
| Polymer C | | | 80 | | | | | | | | | |
| Polymer D | | | | 80 | | | | | | | | |
| Polymer E | | | | | 80 | | | | | | | |
| Polymer F | | | | | | 80 | | | | | | |
| Polymer G | | | | | | | 80 | | | | | |
| Polymer H | | | | | | | | 80 | | | | |
| Polymer I | | | | | | | | | 80 | | | |
| Polymer J | | | | | | | | | | 80 | | 40 |
| Polymer K | | | | | | | | | | | 80 | |
| PAG1 | 2 | 2 | | 2 | 2 | | | 2 | | | 2 | 2 |
| PAG2 | | | 2 | | | 2 | 2 | | 2 | 2 | | |
| PAG3 | | 1 | | 1 | | | | 1 | | 1 | 1 | |
| PAG4 | | | | | 1 | 1 | | | 1 | | | |
| PAG5 | | | | | | | | | | | | |
| PAG6 | 1 | | 1 | | | | 1 | | | | | 1 |
| PAG7 | | | | | | | | | | | | |
| Dissolution | | | | | | | | | | | | |
| inhibitor | | | | | | | | | | | | |
| Basic | 0.17 | 0.17 | 0.17 | 0.17 | 0.17 | | | | | 0.17 | 0.17 | |
| compound A | | | | | | | | | | | | |
| Basic | | | | | | 0.17 | 0.17 | 0.17 | 0.17 | | | 0.17 |
| compound B | | | | | | | | | | | | |
| Organic acid | 1 | 1 | 1 | | | | 1 | 1 | | | 1 | |
| derivative A | | | | | | | | | | | | |
| Organic acid | | | | 1 | 1 | 1 | | | 1 | 1 | | 1 |
| derivative B | | | | | | | | | | | | |
| Surfactant A | 0.25 | | | | | 0.25 | 0.25 | 0.25 | 0.25 | | | 0.25 |
| Surfactant B | | 0.25 | 0.25 | 0.25 | 0.25 | | | | | 0.25 | 0.25 | |
| Solvent A | 280 | 385 | 385 | 385 | 280 | 280 | 280 | 280 | 280 | 280 | 280 | 385 |
| Solvent B | 105 | | | | 105 | 105 | 105 | 105 | 105 | 105 | 105 | |

TABLE 2

| Composition | Example | | | | | | | | | |
|---|---|---|---|---|---|---|---|---|---|---|
| (pbw) | 13 | 14 | 15 | 16 | 17 | 18 | 19 | 20 | 21 | 22 |
| Polymer A | | | | | | | | | | |
| Polymer B | | | | | | | 40 | | 75 | |
| Polymer C | | | | | | | | | | |
| Polymer D | 40 | | | | | 40 | | | | |
| Polymer E | | | | | 20 | 40 | 40 | | | 50 |
| Polymer F | | | | | | | | | | 30 |
| Polymer G | | 40 | 20 | 40 | 60 | | | 45 | | |
| Polymer H | | | | | | | | 35 | | |
| Polymer I | | | 60 | | | | | | | |
| Polymer J | 40 | 40 | | | | | | | | |
| Polymer K | | | | 40 | | | | | | |
| PAG1 | | | 1 | 1 | | 1 | | | 2 | |
| PAG2 | 1 | 1 | | | 2 | | 1 | 1 | | 1 |
| PAG3 | 1 | | | 1 | | 1 | | | | 1 |
| PAG4 | | 1 | 1 | | | | 1 | 1 | | |
| PAG5 | 1 | | 1 | 1 | 1 | | | 1 | 1 | 1 |
| PAG6 | | 1 | | | | 1 | 1 | | | |
| PAG7 | | | | | | | | | | |
| Dissolution | | | | | | | | | 5 | |
| inhibitor | | | | | | | | | | |
| Basic | 0.17 | | 0.17 | 0.17 | | 0.17 | | 0.17 | 0.17 | |
| compound A | | | | | | | | | | |
| Basic | | 0.17 | | | 0.17 | | 0.17 | | | 0.17 |
| compound B | | | | | | | | | | |
| Organic acid | 1 | | 1 | 1 | 1 | | | | 1 | 0.5 |
| derivative A | | | | | | | | | | |
| Organic acid | | 1 | | | | 1 | 1 | 1 | | 0.5 |
| derivative B | | | | | | | | | | |
| Surfactant A | 0.25 | 0.25 | | | | | | 0.25 | 0.25 | |
| Surfactant B | | | 0.25 | 0.25 | 0.25 | 0.25 | 0.25 | | | 0.25 |
| Solvent A | 385 | 280 | 280 | 280 | 385 | 385 | 385 | 280 | 385 | 280 |
| Solvent B | | 105 | 105 | 105 | | | | 105 | | 105 |

TABLE 3

| composition | Comparative Example | | |
|---|---|---|---|
| (pbw) | 1 | 2 | 3 |
| Polymer A | 80 | 40 | |
| Polymer E | | 40 | |
| Polymer K | | | 80 |
| PAG3 | | | 1 |
| PAG6 | 1 | | |
| PAG7 | 2 | 3 | 2 |
| Dissolution inhibitor | | | |
| Basic compound A | | 0.17 | 0.17 |
| Basic compound B | 0.17 | | |
| Organic acid derivative A | 1 | 1 | |
| Organic acid derivative B | | | 1 |
| Surfactant A | 0.25 | 0.25 | |
| Surfactant B | | | 0.25 |
| Solvent A | 385 | 385 | 280 |
| Solvent B | | | 105 |

TABLE 4

| | | | | | | 24 hr PED |
|---|---|---|---|---|---|---|
| | | | | DOF at | | dimensional |
| | Sensitivity | Resolution | | 0.18 μm | Off-focus | stability |
| | (mJ/cm²) | (μm) | Profile | (μm) | profile* | (nm) |
| Example 1 | 35 | 0.17 | rectangular | 0.9 | rectangular | −8 |
| Example 2 | 30 | 0.15 | rectangular | 0.9 | rectangular | −9 |
| Example 3 | 37 | 0.16 | rectangular | 0.9 | rectangular | −10 |
| Example 4 | 33 | 0.17 | rectangular | 0.9 | rectangular | −5 |
| Example 5 | 30 | 0.15 | rectangular | 1.2 | rectangular | 5 |
| Example 6 | 32 | 0.15 | rectangular | 1.1 | rectangular | 5 |
| Example 7 | 35 | 0.16 | rectangular | 1.0 | rectangular | −5 |
| Example 8 | 32 | 0.15 | rectangular | 1.1 | rectangular | 8 |
| Example 9 | 35 | 0.16 | rectangular | 1.0 | rectangular | 10 |
| Example 10 | 34 | 0.16 | rectangular | 1.1 | rectangular | 7 |
| Example 11 | 33 | 0.15 | rectangular | 1.1 | rectangular | 7 |
| Example 12 | 35 | 0.16 | rectangular | 1.0 | rectangular | −6 |
| Example 13 | 43 | 0.17 | rectangular | 1.1 | rectangular | −5 |
| Example 14 | 38 | 0.16 | rectangular | 1.1 | rectangular | −5 |
| Example 15 | 47 | 0.17 | rectangular | 1.0 | rectangular | 5 |
| Example 16 | 45 | 0.16 | rectangular | 1.1 | rectangular | 5 |
| Example 17 | 39 | 0.16 | rectangular | 1.1 | rectangular | −5 |
| Example 18 | 40 | 0.16 | rectangular | 1.1 | rectangular | −5 |
| Example 19 | 38 | 0.15 | rectangular | 1.1 | rectangular | −7 |
| Example 20 | 45 | 0.16 | rectangular | 1.0 | rectangular | 6 |
| Example 21 | 42 | 0.16 | rectangular | 0.9 | rectangular | −10 |
| Example 22 | 42 | 0.16 | rectangular | 1.0 | rectangular | 5 |
| Comparative | | forward | 0.8 | forward | −10 | |
| Example 1 | 38 | 0.17 | taper | | taper | |
| Comparative | 38 | 0.17 | rectangular | 0.8 | rectangular | −7 |
| Example 2 | | | | | | |
| Comparative | 35 | 0.17 | rectangular | 0.9 | rectangular | 5 |
| Example 3 | | | | | | |

*the shape of a pattern obtained when the focus was shifted −0.4 μm to minus side upon DOF measurement at 0.18 μm

TABLE 5

| | | | | | Debris |
|---|---|---|---|---|---|
| | | | 100 day | Debris | after |
| | Disso- | Appli- | storage | after | resist |
| | lution | cation | stability | development | peeling |
| Example 1 | good | good | good | good | good |
| Example 2 | good | good | good | good | good |
| Example 3 | good | good | good | good | good |
| Example 4 | good | good | good | good | good |
| Example 5 | good | good | good | good | good |
| Example 6 | good | good | good | good | good |
| Example 7 | good | good | good | good | good |
| Example 8 | good | good | good | good | good |
| Example 9 | good | good | good | good | good |
| Example 10 | good | good | good | good | good |
| Example 11 | good | good | good | good | good |
| Example 12 | good | good | good | good | good |
| Example 13 | good | good | good | good | good |
| Example 14 | good | good | good | good | good |
| Example 15 | good | good | good | good | good |
| Example 16 | good | good | good | good | good |
| Example 17 | good | good | good | good | good |
| Example 18 | good | good | good | good | good |
| Example 19 | good | good | good | good | good |
| Example 20 | good | good | good | good | good |
| Example 21 | good | good | good | good | good |
| Example 22 | good | good | good | good | good |
| Comparative | good | good | good | poor | poor |
| Example 1 | | | | | |
| Comparative | good | good | good | poor | poor |
| Example 2 | | | | | |
| Comparative | good | good | good | poor | unacceptable |
| Example 3 | | | | | |

There have been described photoacid generators capable of generating 2,4,6-triisopropylbenzenesulfonic acid upon exposure to actinic radiation and chemically amplified positive resist compositions comprising the same. Due to the low diffusion of 2,4,6-triisopropylbenzenesulfonic acid, the compositions have many advantages including improved resolution, improved focus latitude, and minimized line width variation or shape degradation even on long-term PED. Despite the highly lipophilic structure, the debris left after coating, development and peeling is minimized. Even when a basic organic antireflection coating is used as the underlay, the resist compositions are resistant to deactivation by any base from the substrate. Because of improved pattern profile and high resolution, the compositions are suited for microfabrication, especially by deep UV lithography.

Japanese Patent Application No. 2002-233510 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A photoacid generator for chemically amplified positive resist compositions, having the general formula (1): 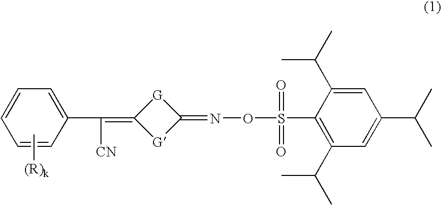
wherein G and G′ each are a sulfur atom or —CH═CH—, excluding the case where both G and G′ are sulfur atoms, R which may be the same or different is a hydrogen atom, fluorine atom, chlorine atom, or substituted or unsubstituted straight, branched or cyclic alkyl or alkoxy group of 1 to 4 carbon atoms, and k is an integer of 0 to 4.

2. A photoacid generator for chemically amplified positive resist compositions, having the general formula (1a): 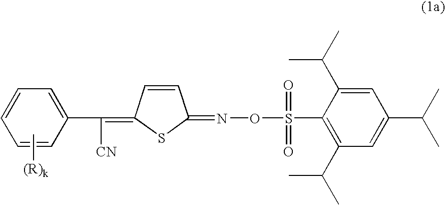
wherein R which may be the same or different is a hydrogen atom, fluorine atom, chlorine atom, or substituted or unsubstituted straight, branched or cyclic alkyl or alkoxy group of 1 to 4 carbon atoms, and k is an integer of 0 to 4.

3. A photoacid generator for chemically amplified positive resist compositions, having the general formula (1b): 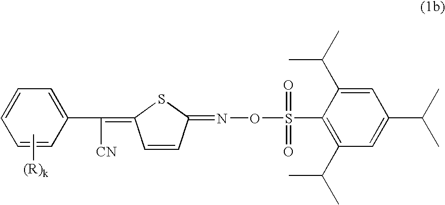
wherein R which may be the same or different is a hydrogen atom, fluorine atom, chlorine atom, or substituted or unsubstituted straight, branched or cyclic alkyl or alkoxy group of 1 to 4 carbon atoms, and k is an integer of 0 to 4.

4. A chemically amplified positive resist composition comprising
(A) a resin which changes its solubility in an alkaline developer under the action of an acid, and
(B) the photoacid generator of claim 1.

5. The resist composition of claim 4, further comprising
(C) a compound capable of generating an acid upon exposure to radiation, other than component (B).

6. The resist composition of claim 4 wherein the resin (A) has such substituent groups having C—O—C linkages that the solubility in an alkaline developer changes as a result of scission of the C—O—C linkages under the action of an acid.

7. The resist composition of claim 6 wherein the resin (A) is a polymer containing phenolic hydroxyl groups in which hydrogen atoms of the phenolic hydroxyl groups are substituted with acid labile groups of one or more types in a proportion of more than 0 mol % to 80 mol % on the average of the entire hydrogen atoms of the phenolic hydroxyl groups, the polymer having a weight average molecular weight of 3,000 to 100,000.

8. The resist composition of claim 7 wherein the resin (A) is a polymer comprising recurring units of the following general formula (2a): 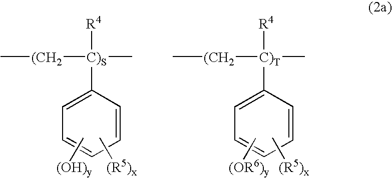
wherein R⁴ is hydrogen or methyl, R⁵ is a straight, branched or cyclic alkyl group of 1 to 8 carbon atoms, x is 0 or a positive integer, y is a positive integer, satisfying x+y≦5, R⁶ is an acid labile group, S and T are positive integers, satisfying 0<T/(S+T)≦0.8,
wherein the polymer contains units in which hydrogen atoms of phenolic hydroxyl groups are partially substituted with acid labile groups of one or more types, a proportion of the acid labile group-bearing units is on the average from more than 0 mol % to 80 mol % based on the entire polymer, and the polymer has a weight average molecular weight of 3,000 to 100,000.

9. The resist composition of claim 6 wherein the resin (A) is a polymer comprising recurring units of the following general formula (2a′): 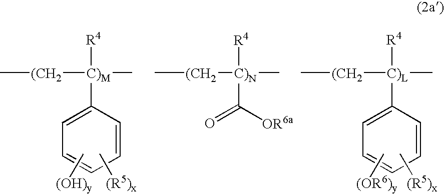
wherein R⁴ is hydrogen or methyl, R⁵ is a straight, branched or cyclic alkyl group of 1 to 8 carbon atoms, R⁶ is an acid labile group, R^{6a} is hydrogen or an acid labile group, at least some of R^{6a} being acid labile groups, x is 0 or a positive integer, y is a positive integer, satisfying x+y≦5, M and N are positive integers, L is 0 or a positive integer, satisfying 0<N/(M+N+L)≦0.5 and 0<(N+L)/(M+N+L)≦0.8,
wherein the polymer contains on the average from more than 0 mol % to 50 mol % of those units based on acrylate and methacrylate, and also contains on the average from more than 0 mol % to 80 mol % of acid labile group-bearing units, based on the entire polymer, and the polymer has a weight average molecular weight of 3,000 to 100,000.

10. The resist composition of claim 6 wherein the resin (A) is a polymer comprising recurring units of the following general formula (2a″): 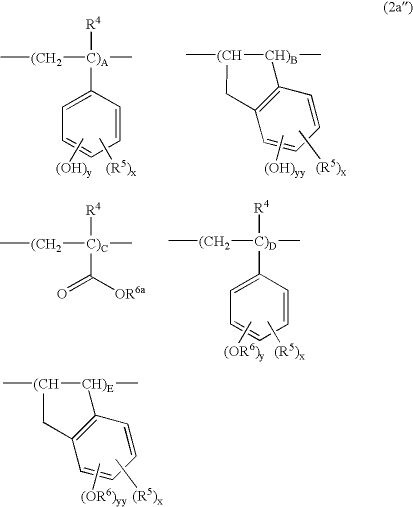
wherein R⁴ is hydrogen or methyl, R⁵ is a straight, branched or cyclic alkyl group of 1 to 8 carbon atoms, R⁶ is an acid labile group, R^{6a} is hydrogen or an acid labile group, at least some of R^{6a} being acid labile groups, x is 0 or a positive integer, y is a positive integer, satisfying x+y≦5, yy is 0 or a positive integer, satisfying x+yy≦4, A and B are positive integers, C, D and E each are 0 or a positive integer, satisfying 0<(B+E)/(A+B+C+D+E)≦0.5 and 0<(C+D+E)/(A+B+C+D+E)≦0.8,
wherein the polymer contains on the average from more than 0 mol % to 50 mol % of those units based on indene and/or substituted indene, and also contains on the average from more than 0 mol % to 80 mol % of acid labile group-bearing units, based on the entire polymer, and the polymer has a weight average molecular weight of 3,000 to 100,000.

11. The resist composition of claim 7 wherein the acid labile group is selected from the class consisting of groups of the following general formulae (4) to (7), tertiary alkyl groups of 4 to 20 carbon atoms, trialkylsilyl groups whose alkyl moieties each have 1 to 6 carbon atoms, oxoalkyl groups of 4 to 20 carbon atoms, and aryl-substituted alkyl groups of 7 to 20 carbon atoms, 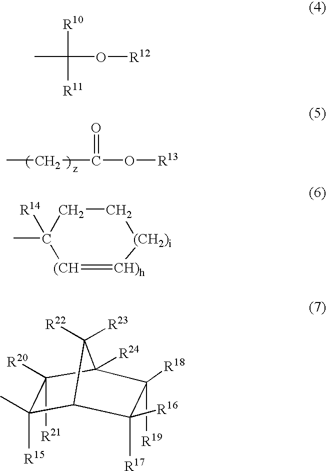
wherein R¹⁰ and R¹¹ each are hydrogen or a straight, branched or cyclic alkyl group having 1 to 18 carbon atoms, and R¹² is a monovalent hydrocarbon group of 1 to 18 carbon atoms which may contain a heteroatom, a pair of R¹⁰ and R¹¹, R¹⁰ and R¹², or R¹¹ and R¹² may together form a ring, with the proviso that R¹⁰, R¹¹, and R¹² each are a straight or branched alkylene of 1 to 18 carbon atoms when they form a ring,
R¹³ is a tertiary alkyl group of 4 to 20 carbon atoms, a trialkysilyl group whose alkyl moieties each have 1 to 6 carbon atoms, an oxoalkyl group of 4 to 20 carbon atoms, or a group of the formula (4), z is an integer of 0 to 6,
R¹⁴ is a straight, branched or cyclic alkyl group of 1 to 8 carbon atoms or an aryl group of 6 to 20 carbon atoms which may be substituted, h is 0 or 1, i is 0, 1, 2 or 3, satisfying 2h+i=2 or 3,
R¹⁵ is a straight, branched or cyclic alkyl group of 1 to 8 carbon atoms or an aryl group of 6 to 20 carbon atoms which may be substituted, R¹⁶ to R²⁵ are each independently hydrogen or a monovalent hydrocarbon group of 1 to 15 carbon atoms which may contain a heteroatom, any two of R¹⁶ to R²⁵, taken together, may form a ring, each of the ring-forming two of R¹⁶ to R²⁵ is a divalent hydrocarbon group of 1 to 15 carbon atoms which may contain a heteroatom, or two of R¹⁶ to R²⁵ which are attached to adjoining carbon atoms may bond together directly to form a double bond.

12. The resist composition of claim 4, further comprising (D) a basic compound.

13. The resist composition of claim 4, further comprising (E) an organic acid derivative.

14. The resist composition of claim 4, further comprising an organic solvent which is a propylene glycol alkyl ether acetate, an alkyl lactate or a mixture thereof.

15. A process for forming a pattern, comprising the steps of:
(i) applying the resist composition of claim 4 onto a substrate to form a coating,
(ii) heat treating the coating and exposing the coating to high energy radiation with a wavelength of up to 300 nm or electron beam through a photomask,
(iii) optionally heat treating the exposed coating, and developing the coating with a developer.
